(19) United States
(12) Patent Application Publication
(10) Pub. No.: US 2025/0359324 A1
(43) Pub. Date: Nov. 20, 2025

(54) SEMICONDUCTOR STRUCTURE

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/665,238

(22) Filed: May 15, 2024

(51) Int. Cl. H01L 27/118; H03K 19/20

(52) U.S. Cl. CPC H10D 84/907; H03K 19/20; H10D 84/953; H10D 84/959; H10D 84/981

(57) ABSTRACT

A semiconductor structure includes a first transistor, a second transistor, a gate structure, and a first source/drain contact. The first transistor includes first nanostructures stacked from each other in a Z-direction, and a first source/drain feature and a second source/drain feature on opposite sides of the first nanostructures in an X-direction. The second transistor is arranged with the first transistor in a Y-direction. The second transistor includes second nanostructures stacked from each other in the Z-direction, and a third source/drain feature and a fourth source/drain feature on opposite sides of the second nanostructures in the X-direction. The gate structure extends in the Y-direction and wraps around the first nanostructures and the second nanostructures. The first source/drain contact extends in the Y-direction and is under and electrically connected to the second source/drain feature and the fourth source/drain feature.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip, in portion or entirety, in accordance with some embodiments of the present disclosure.

FIGS. 2A, 2B, 2C, 2D, and 2E are circuit schematics of various STD cells in in the logic region of the IC chip, in accordance with some embodiments of the present disclosure.

FIG. 3 is a perspective view of a GAA transistor, in accordance with some embodiments of the present disclosure.

FIGS. 4A and 4B are top views (or layouts) of a semiconductor structure in the logic region of the IC chip, in accordance with some embodiments of the present disclosure, in which FIG. 4A illustrates the features in the device region and the front-side interconnection structure, and FIG. 4B illustrates the features in the device region and the back-side interconnection structure.

FIG. 4C is an X-Z cross-sectional view of the semiconductor structure along a line A-A′ in FIGS. 4A and 4B, in accordance with some embodiments of the present disclosure.

FIG. 4D is an X-Z cross-sectional view of the semiconductor structure along a line B-B′ in FIGS. 4A and 4B, in accordance with some embodiments of the present disclosure.

FIG. 4E is a Y-Z cross-sectional view of the semiconductor structure along a line C-C′ in FIGS. 4A and 4B, in accordance with some embodiments of the present disclosure.

FIG. 4F is a Y-Z cross-sectional view of the semiconductor structure along a line D-D′ in FIGS. 4A and 4B, in accordance with some embodiments of the present disclosure.

FIG. 5 is a top view (or a layout) of the semiconductor structure in the logic region of the IC chip, in accordance with some alternative embodiments of the present disclosure, in which FIG. 5 illustrates the features in the device region and the front-side interconnection structure.

FIGS. 6A and 6B are Y-Z cross-sectional views of the semiconductor structure along the lines C-C′ and D-D′ of FIGS. 4A and 4B, respectively, in accordance with some alternative embodiments of the present disclosure.

FIGS. 6C and 6D are Y-Z cross-sectional views of the semiconductor structure along the lines C-C′ and D-D′ of FIGS. 4A and 4B, respectively, in accordance with some alternative embodiments of the present disclosure.

FIGS. 7A and 7B are top views (or layouts) of the semiconductor structure in the logic region of the IC chip, in accordance with some alternative embodiments of the present disclosure, in which FIG. 7A illustrates the features in the device region and the front-side interconnection structure, and FIG. 7B illustrates the features in the device region and the back-side interconnection structure.

FIG. 7C is an X-Z cross-sectional view of the semiconductor structure along the line A-A′ in FIGS. 7A and 7B, in accordance with some alternative embodiments of the present disclosure.

FIG. 7D is an X-Z cross-sectional view of the semiconductor structure along the line B-B′ in FIGS. 7A and 7B, in accordance with some alternative embodiments of the present disclosure.

FIG. 7E is a Y-Z cross-sectional view of the semiconductor structure along the line C-C′ in FIGS. 7A and 7B, in accordance with some alternative embodiments of the present disclosure.

FIG. 7F is a Y-Z cross-sectional view of the semiconductor structure along the line D-D′ in FIGS. 7A and 7B, in accordance with some alternative embodiments of the present disclosure.

FIGS. 8A and 8B are top views (or layouts) of the semiconductor structure in the logic region of the IC chip, in accordance with some alternative embodiments of the present disclosure, in which FIG. 8A illustrates the features in the device region and the front-side interconnection structure, and FIG. 8B illustrates the features in the device region and the back-side interconnection structure.

FIG. 8C is an X-Z cross-sectional view of the semiconductor structure along the line A-A′ in FIGS. 8A and 8B, in accordance with some alternative embodiments of the present disclosure.

FIG. 8D is an X-Z cross-sectional view of the semiconductor structure along the line B-B′ in FIGS. 8A and 8B, in accordance with some alternative embodiments of the present disclosure.

FIG. 8E is a Y-Z cross-sectional view of the semiconductor structure along the line C-C′ in FIGS. 8A and 8B, in accordance with some alternative embodiments of the present disclosure.

FIG. 8F is a Y-Z cross-sectional view of the semiconductor structure along the line D-D′ in FIGS. 8A and 8B, in accordance with some alternative embodiments of the present disclosure.

FIGS. 9A and 9B are top views (or layouts) of the semiconductor structure in the logic region of the IC chip, in accordance with some alternative embodiments of the present disclosure, in which FIG. 9A illustrates the features in the device region and the front-side interconnection structure, and FIG. 9B illustrates the features in the device region and the back-side interconnection structure.

FIG. 9C is an X-Z cross-sectional view of the semiconductor structure along the line A-A′ in FIGS. 9A and 9B, in accordance with some alternative embodiments of the present disclosure.

FIG. 9D is an X-Z cross-sectional view of the semiconductor structure along the line B-B′ in FIGS. 9A and 9B, in accordance with some alternative embodiments of the present disclosure.

FIG. 9E is a Y-Z cross-sectional view of the semiconductor structure along the line C-C′ in FIGS. 9A and 9B, in accordance with some alternative embodiments of the present disclosure.

FIG. 9F is a Y-Z cross-sectional view of the semiconductor structure along the line D-D′ in FIGS. 9A and 9B, in accordance with some alternative embodiments of the present disclosure.

FIGS. 10A and 10B are top views (or layouts) of the semiconductor structure in the logic region of the IC chip, in accordance with some alternative embodiments of the present disclosure, in which FIG. 10A illustrates the features in the device region and the front-side interconnection structure, and FIG. 10B illustrates the features in the device region and the back-side interconnection structure.

FIG. 10C is an X-Z cross-sectional view of the semiconductor structure along the line A-A′ in FIGS. 10A and 10B, in accordance with some alternative embodiments of the present disclosure.

FIG. 10D is an X-Z cross-sectional view of the semiconductor structure along the line B-B′ in FIGS. 10A and 10B, in accordance with some alternative embodiments of the present disclosure.

FIG. 10E is a Y-Z cross-sectional view of the semiconductor structure along the line C-C′ in FIGS. 10A and 10B, in accordance with some alternative embodiments of the present disclosure.

FIG. 10F is a Y-Z cross-sectional view of the semiconductor structure along the line D-D′ in FIGS. 10A and 10B, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures of circuit cells having field-effect transistors (FETs), such as three-dimensional gate-all-around (GAA) transistors, in an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include semiconductor structures having a back-side source/drain contact under and electrically connected to source/drain features of two adjacent transistors sharing the same gate structure, such that the resistance of the local interconnection is reduced. The details of the present disclosure are described below in conjunction with the accompanying drawings, which illustrate the layout and structure of circuit cells, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise noted.

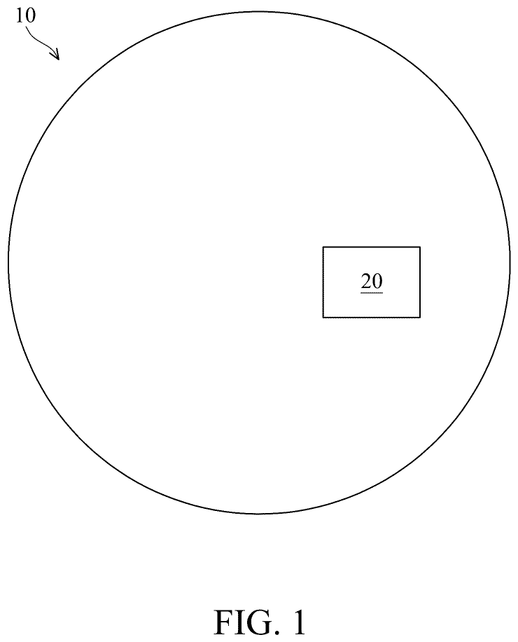

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), N-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or combinations thereof. The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. As shown in FIG. 1, the IC chip 10 includes a logic region 20. The logic region 20 may include an array of circuit cells having various logic cells or standard (STD) cells. The logic cells or STD cells may include transistors and interconnect structures that combine to provide a logic device and/or a logic function, such as an inverter, an AND, an NAND, an OR, an NOR, a NOT, an XOR, an XNOR, a Flip-Flop, other suitable logic devices, or combinations thereof. FIG. 1 has been simplified for the sake of clarity to better understand the inventive concepts of the present disclosure. Additional features can be added in the IC chip 10, and some of the features described herein can be replaced, modified, or eliminated in other embodiments of the IC chip 10.

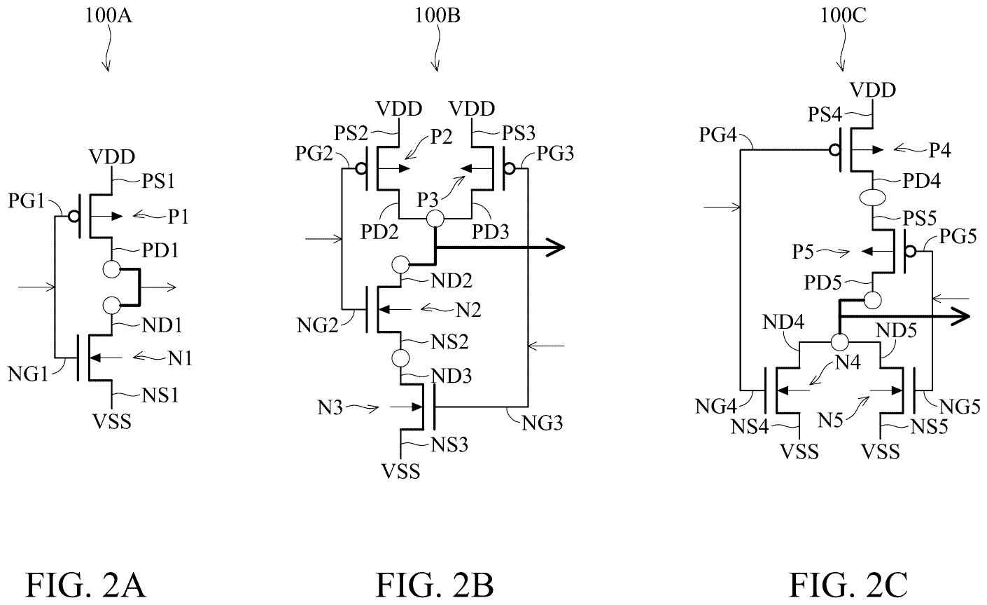

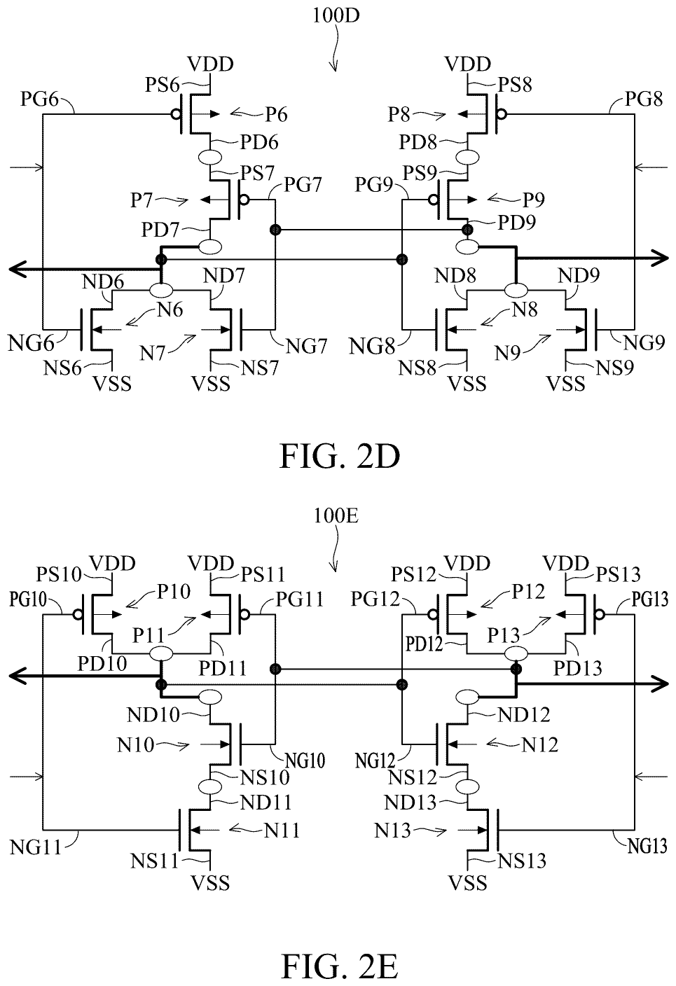

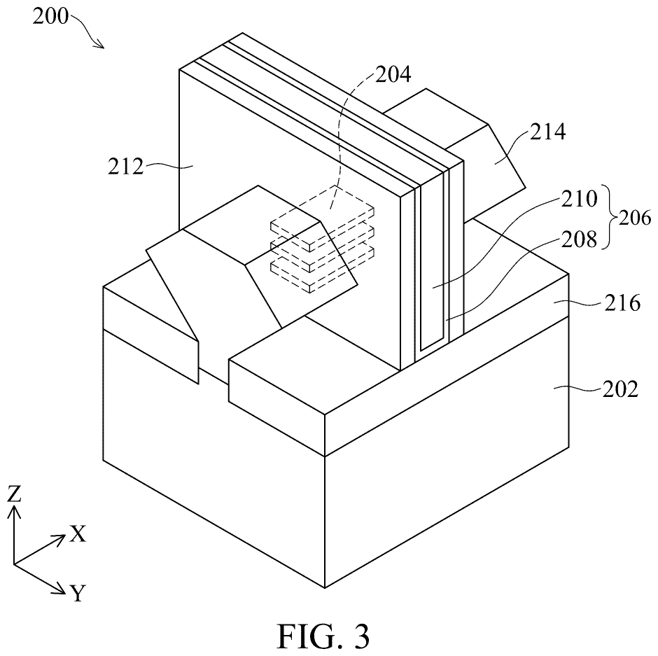

FIGS. 2A to 2E are circuit schematics of various STD cells in the array of circuit cells in the logic region 20 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

FIG. 2D shows a flip-flop (also referred to as a flip-flop device or a flip-flop cell) 100D including N-type transistors N6, N7, N8, N9 and P-type transistors P6, P7, P8, P9. The N-type transistor N6 includes a source terminal NS6, a drain terminal ND6, and a gate terminal NG6; the N-type transistor N7 includes a source terminal NS7, a drain terminal ND7, and a gate terminal NG7; the N-type transistor N8 includes a source terminal NS8, a drain terminal ND8, and a gate terminal NG8; and the N-type transistor N9 includes a source terminal NS9, a drain terminal ND9, and a gate terminal NG9. The P-type transistor P6 includes a source terminal PS6, a drain terminal PD6, and a gate terminal PG6; the P-type transistor P7 includes a source terminal PS7, a drain terminal PD7, and a gate terminal PG7; the P-type transistor P8 includes a source terminal PS8, a drain terminal PD8, and a gate terminal PG8; and the P-type transistor P9 includes a source terminal PS9, a drain terminal PD9, and a gate terminal PG9.

As shown in FIG. 2D, the flip-flop 100D is a set-reset (SR) NOR latch. The NOR latch may include a pair of cross-coupled NOR. Specifically, the output terminal of a first NOR is coupled to the second input terminal of a second NOR, and the output terminal of the second NOR is coupled to the second input terminal of the first NOR. The details of the other connections of the flip-flop 100D are similar to the NOR 100C, and may not be described in detail herein.

FIG. 2E shows a flip-flop 100E including N-type transistors N10, N11, N12, N13 and P-type transistors P10, P11, P12, P13. The N-type transistor N10 includes a source terminal NS10, a drain terminal ND10, and a gate terminal NG10; the N-type transistor N11 includes a source terminal NS11, a drain terminal ND11, and a gate terminal NG11; the N-type transistor N12 includes a source terminal NS12, a drain terminal ND12, and a gate terminal NG12; and the N-type transistor N13 includes a source terminal NS13, a drain terminal ND13, and a gate terminal NG13. The P-type transistor P10 includes a source terminal PS10, a drain terminal PD10, and a gate terminal PG10; the P-type transistor P11 includes a source terminal PS11, a drain terminal PD11, and a gate terminal PG11; the P-type transistor P12 includes a source terminal PS12, a drain terminal PD12, and a gate terminal PG12; and the P-type transistor P13 includes a source terminal PS13, a drain terminal PD13, and a gate terminal PG13.

As shown in FIG. 2E, the flip-flop 100E is a SR NAND latch. The NAND latch may include a pair of cross-coupled NAND. Specifically, the output terminal of a first NAND is coupled to the first input terminal of a second NAND, and the output terminal of the second NAND is coupled to the first input terminal of the first NAND. The details of the other connections of the flip-flop 100E are similar to the NAND 100B, and may not be described in detail herein.

Each of the circuit cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, an exemplary GAA transistor is illustrated in FIG. 3. However, it should be understood that the application should not be limited to a particular type of device, except as specifically claimed.

Referring to FIG. 3, a perspective view of an exemplary GAA transistor 200 is illustrated. The GAA transistor 200 is formed over a substrate 202. The substrate 202 may contains a semiconductor material, such as bulk silicon (Si). The GAA transistor 200 also includes one or more nanostructures 204 (dash lines) extending in the X-direction and vertically stacked (or arranged) in the Z-direction. More specifically, the nanostructures 204 are spaced apart from each other in the Z-direction. In some embodiments, the nanostructures 204 may also be referred to as channels, channel layers, nanosheets, or nanowires.

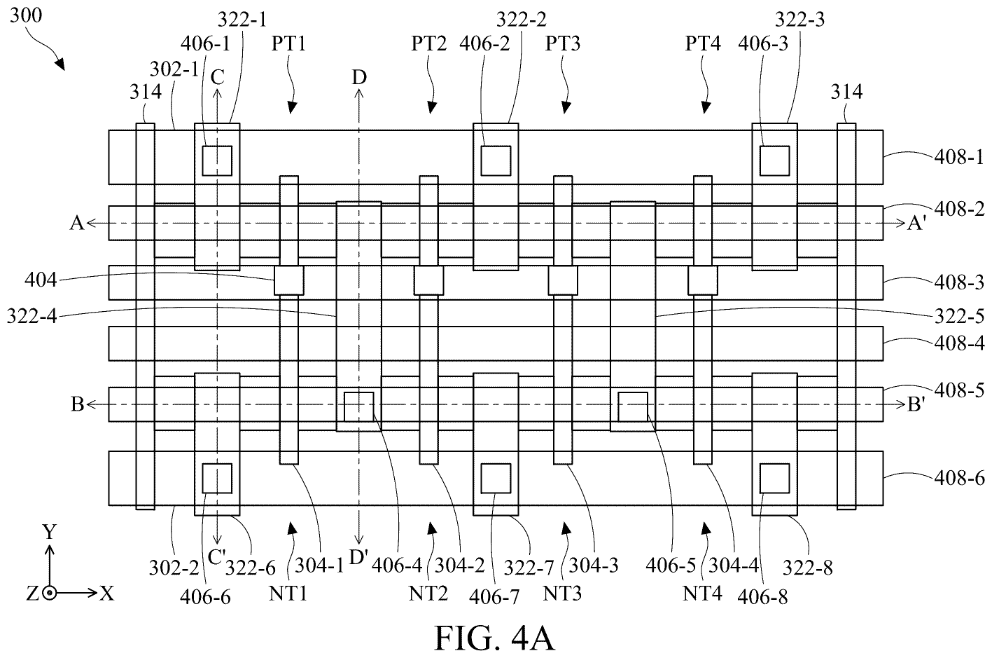

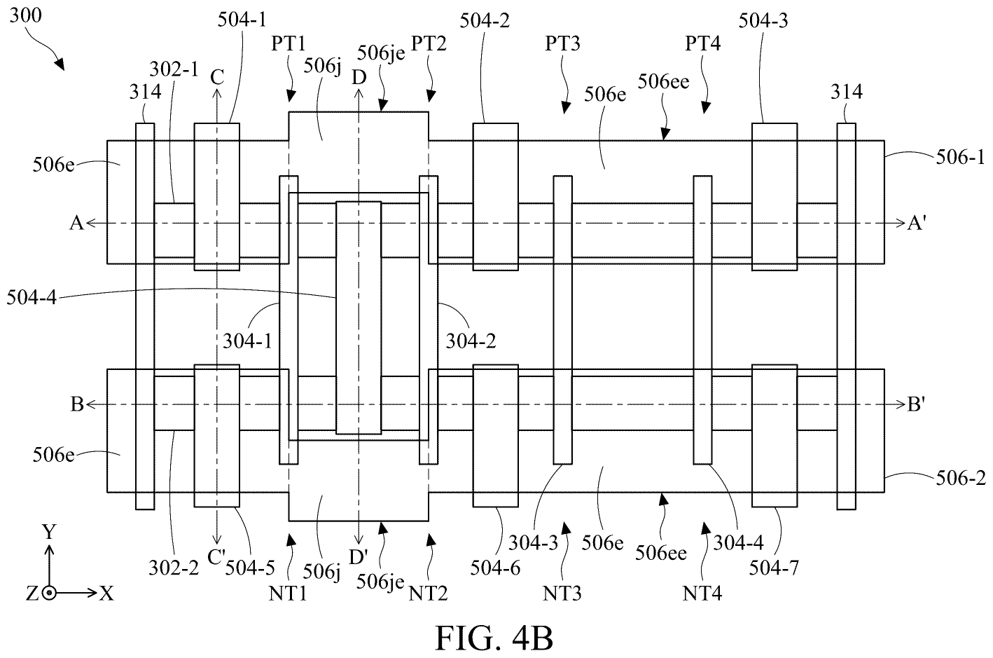

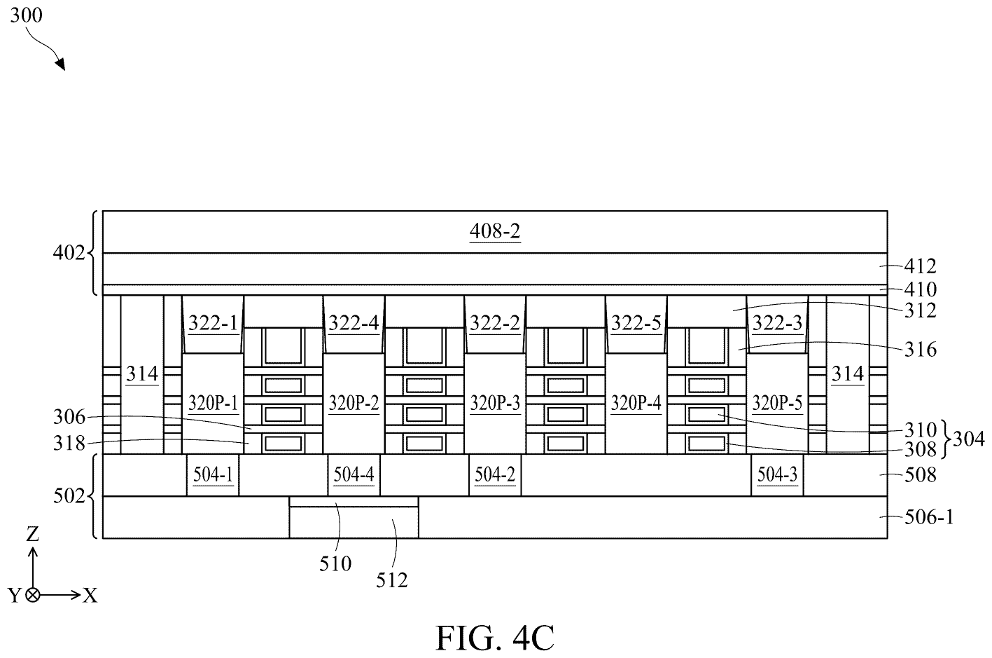

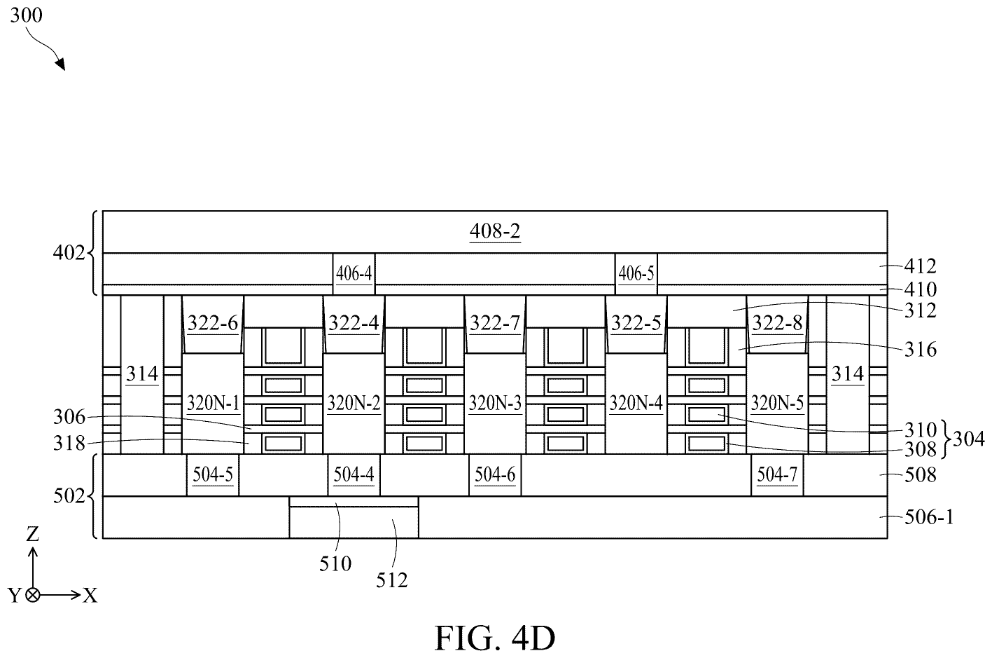

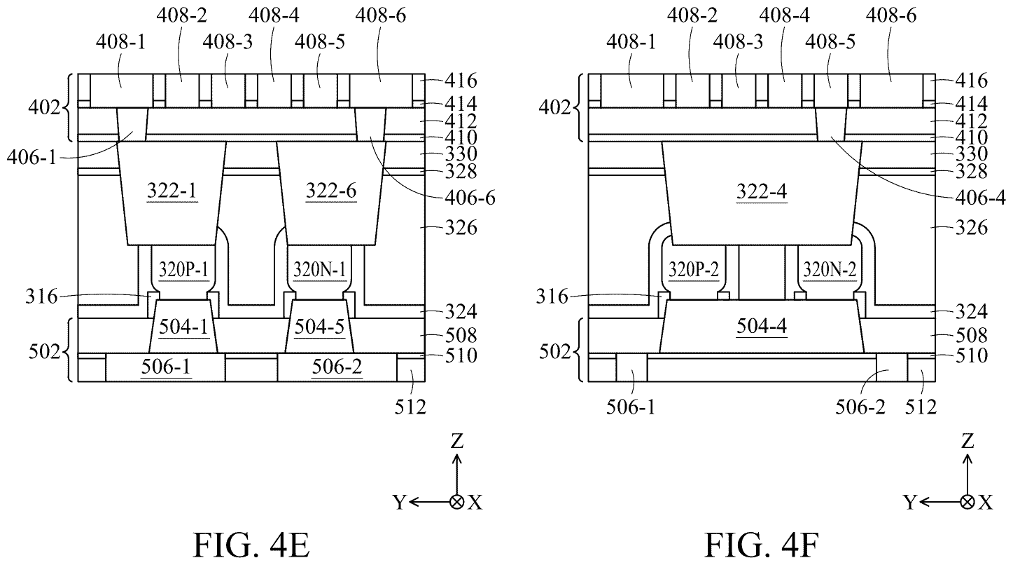

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 2, may refer to FIGS. 4C, 4D, and 4E). As shown in FIG. 2, gate spacers 212 are on sidewalls of the gate structure 206 and over the nanostructures 204 (not shown in FIG. 2, may refer to FIGS. 4C and 4D)

The GAA transistor 200 further includes source/drain features 214. As shown in FIG. 2, two source/drain features 214 are on opposite sides of the gate structure 206. The nanostructures 204 (dash lines) extend in the X-direction to connect one source/drain feature 214 to the other source/drain feature 214. The source/drain features 214 may also be referred to as source/drain, or source/drain regions. In some embodiments, source/drain feature(s) may refer to a source or a drain, individually or collectively dependent upon the context.

Isolation feature 216 is over the substrate 202 and under the gate dielectric layer 208, the gate electrode 210, and the gate spacers 212. The isolation feature 216 is used for isolating the GAA transistor 200 from other devices. The isolation feature 216 may include silicon oxide, silicon nitride, silicon oxynitride, other suitable isolation material (for example, including silicon, oxygen, nitrogen, carbon, or other suitable isolation constituent), or combinations thereof. The isolation feature 216 may include different structures, such as shallow trench isolation (STI) structures, deep trench isolation (DTI) structures, and/or local oxidation of silicon (LOCOS) structures. Therefore, the isolation feature 216 is also referred as to as a STI feature or DTI feature. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

FIGS. 4A and 4B are top views (or layouts) of a semiconductor structure 300 in the logic region 20 of the IC chip 10, in accordance with some embodiments of the present disclosure. FIG. 4A illustrates the features in the device region (including transistors and source/drain contacts) and the front-side interconnection structure (including vias and metal conductors), and FIG. 4B illustrates the features in the device region and the back-side interconnection structure.

FIG. 4C is an X-Z cross-sectional view of the semiconductor structure 300 along a line A-A′ in FIGS. 4A and 4B, in accordance with some embodiments of the present disclosure. FIG. 4D is an X-Z cross-sectional view of the semiconductor structure 300 along a line B-B′ in FIGS. 4A and 4B, in accordance with some embodiments of the present disclosure. FIG. 4E is a Y-Z cross-sectional view of the semiconductor structure 300 along a line C-C′ in FIGS. 4A and 4B, in accordance with some embodiments of the present disclosure. FIG. 4F is a Y-Z cross-sectional view of the semiconductor structure 300 along a line D-D′ in FIGS. 4A and 4B, in accordance with some embodiments of the present disclosure.

Referring to FIGS. 4A and 4B, the semiconductor structure 300 includes active areas, such as active areas 302-1 to 302-2 (may be collectively referred to as the active areas 302). The active areas 302 extend lengthwise in the X-direction and are arranged in the Y-direction. Each of active areas 302 includes channel regions (including nanostructures 306), source regions, and drain regions (where source regions and drain regions are collectively referred to as source/drain regions herein) of transistors.

The semiconductor structure 300 further includes gate structures, such as gate structures 304-1 to 304-4 (may be collectively referred to as the gate structures 304) that extend lengthwise in the Y-direction. The X-direction and the Y-direction are perpendicular. The gate structures 304-1 to 304-4 are disposed over the channel regions of the respective active areas 302-1 and 302-2 (i.e., (vertically stacked) nanostructures 306) and disposed between respective source/drain regions of the active areas 302-1 and 302-2 (i.e., source/drain features 320N and 320P). In some embodiments, the gate structures 304-1 to 304-4 wrap and/or surround suspended, vertically stacked nanostructures 306 in the channel regions of the active areas 302-1 and 302-2, respectively (as shown in FIGS. 4A and 4B).

The gate structures engage the active areas to form the transistors discussed above. As shown in FIGS. 4A and 4B, the gate structure 304-1 extends across the active areas 302-1 and 302-2 in the top view and engages the active area 302-1 and 302-2 to respectively form transistor PT1 and transistor NT1; the gate structure 304-2 extends across the active areas 302-1 and 302-2 in the top view and engages the active area 302-1 and 302-2 to respectively form transistor PT2 and transistor NT2; the gate structure 304-3 extends across the active areas 302-1 and 302-2 in the top view and engages the active area 302-1 and 302-2 to respectively form transistor PT3 and transistor NT3; and the gate structure 304-4 extends across the active areas 302-1 and 302-2 in the top view and engages the active area 302-1 and 302-2 to respectively form transistor PT4 and transistor NT4.

The transistors NT1, NT2, NT3, NT4, PT1, PT2, PT3, and PT4 are also referred to as functional transistors. In some embodiments, the transistors NT1, NT2, NT3, and NT4 are N-type, and thus are also referred to as N-type transistors. In some embodiments, the transistors PT1, PT2, PT3, and PT4 are P-type, and thus are also referred to as P-type transistors. As shown in FIGS. 4A and 4B, the transistors PT1, PT2, PT3, and PT4 are arranged in the X-direction and share the active area 302-1. The transistors NT1, NT2, NT3, and NT4 are also arranged in the X-direction and share the active area 302-2. The PT1, PT2, PT3, and PT4 are respectively arranged with the transistors NT1, NT2, NT3, and NT4 in the Y-direction, as shown in FIGS. 4A and 4B. Furthermore, the transistors PT1 and NT1 share the gate structure 304-1; the transistors PT2 and NT2 share the gate structure 304-2; the transistors PT3 and NT3 share the gate structure 304-3; and the transistors PT4 and NT4 share the gate structure 304-4.

Each of the transistors NT1, NT2, NT3, NT4, PT1, PT2, PT3, and PT4 includes nanostructures 306 in the active areas 302, similar to the nanostructures 204 discussed above. As shown in FIGS. 4C and 4D, the nanostructures 306 are suspended. In some embodiments, three nanostructures 306 are vertically stacked (or vertically arranged) from each other in the Z-direction for one transistor. However, there may be another appropriate number of nanostructures in one transistor. For example, there may be from 2 to 6 nanostructures 306 in one transistor. The nanostructures 306 further extend lengthwise in the X-direction (FIGS. 4A and 4B) and widthwise in the Y-direction (not shown). As shown in FIGS. 4A and 4B, in each of the transistors NT1, NT2, NT3, NT4, PT1, PT2, PT3, and PT4, three nanostructures 306 are spaced apart from each other in the Z-direction.

The nanostructures 306 may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GaInAs, GaInP, and/or GaInAsP. In some embodiments, the nanostructures 306 include silicon for n-type transistors, such as the transistors NT1 to NT4. In other embodiments, the nanostructures 306 include silicon germanium for p-type transistors, such as transistors PT1 to PT4. In some embodiments, the nanostructures 306 are all made of silicon, and the type of the transistors depends on the work function metal layer wrapping around the nanostructures 306. In some embodiments, the nanostructures 306 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Each of the gate structures 304-1 to 304-4 has a gate dielectric layer 308 and a gate electrode layer 310. The gate dielectric layers 308 wrap around each of the nanostructures 306 and the gate electrodes layer 310 wrap around the gate dielectric layer 308. In some embodiments, each of the gate structures 304 further includes an interfacial layer (such as silicon dioxide, silicon oxynitride, or other suitable materials) between the gate dielectric layer 308 and the nanostructures 306. The gate dielectric layers 308 may include oxide with nitrogen doped dielectric material (initial layer) combined with metal content high-K dielectric material (K value (dielectric constant)>13). For example, gate dielectric layers 308 may include hafnium oxide (HfO₂), which has a dielectric constant in a range from about 18 to about 40. Alternatively, the gate dielectric layers 308 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 308 may be formed by chemical oxidation, thermal oxidation, ALD, CVD, and/or other suitable methods.

The gate electrode layer 310 is formed to wrap around the gate dielectric layer 308 and the center portions of the nanostructures 306, as shown in FIGS. 4A and 4B. In some embodiments, the gate electrode layers 310 may include an n-type work function metal layer for n-type transistor (such as the transistors NT1 to NT4) or a p-type work function metal layer for p-type transistor (such as the transistors PT1 to PT4). More specifically, the gate electrode layers 308 may each has n-type work function metal layers between the source/drain features 320N with n-type dopant for n-type transistor (such as the transistors NT1 to NT4) and p-type work function metal layers between the source/drain features 320P with p-type dopant for p-type transistor (such as the transistors PT1 to PT4), in accordance with some embodiments of the present disclosure.

In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

In an embodiment, the p-type work function metal layer is a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, other suitable p-type work function materials, combinations of these, or the like. Additionally, the p-type work function metal layer may be deposited using a deposition process such as ALD, CVD, or the like, although any suitable deposition process may be used.

In some embodiments, the gate electrode layer 310 may include a single layer or alternatively a multi-layer structure. In some embodiments, the gate electrode layer 310 may further include a capping layer, a barrier layer, and a fill material (not shown). The capping layer may be formed adjacent to the gate dielectric layers 308 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

Referring to FIGS. 4C and 4D, the semiconductor structure 300 further include gate top dielectric layers 312 are over the gate dielectric layers 308, the gate electrode layers 310, and the nanostructures 306. The gate top dielectric layer 312 is used for contact etch protection layer. The material of gate top dielectric layer 312 is selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable material.

The semiconductor structure 300 further includes dielectric gate structures 314 for separating the transistors PT1 to PT4 and NT1 to NT4 from other transistors or devices. The dielectric gate structures 314 extend lengthwise in the Y-direction. The dielectric gate structures 314 and the transistors PT1 to PT4 and NT1 to NT4 are arranged in the X-direction. More specifically, as shown in FIGS. 4A and 4B, two dielectric gate structures 314 and the transistors PT1 to PT4 and NT1 to NT4 (or the gate structures 304-1 to 304-4) are arranged in the X-direction. In some embodiments, the transistors PT1 to PT4 and NT1 to NT4 (or the gate structures 304-1 to 304-4) are between the two dielectric gate structures 314, as shown in FIGS. 4A to 4D.

As discussed above, the dielectric gate structures 314 and the gate structures 304 are arranged in the X-direction. In some embodiments, a gate pitch of the gate structures 304 and a gate pitch of one gate structure 304 to one dielectric gate structure 314 are substantially the same. Furthermore, a gate length of the gate structures 106 in the X-direction and a gate length of the dielectric gate structures 314 in the X-direction are the same.

The semiconductor structure 300 further include gate spacers 316 similar to gate spacers 212 discussed above on sidewalls of the gate structures 304 and over the nanostructures 306, as shown in FIGS. 4C and 4D. More specifically, the gate spacers 316 are over the nanostructures 306 and on top sidewalls of the gate structures 304, and thus are also referred to as gate top spacers or top spacers. The gate spacers 316 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 316 may include a single layer or a multi-layer structure.

As shown in FIGS. 4C and 4D, the semiconductor structure 300 further include inner spacers 318 on the sidewalls of the gate structures 304 and below the topmost nanostructures 306. Furthermore, the inner spacers 318 are laterally between the source/drain features 320N (or 320P) and the gate structures 304. The inner spacers 318 are also vertically between adjacent nanostructures 306. The inner spacers 318 may include a dielectric material having higher K value (dielectric constant) than the gate spacers 316 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In some embodiments, the thickness of the gate spacers 316 in the X-direction and the thickness of the inner spacers 318 in the X-direction are the same.

Referring to FIGS. 4C to 4F, the semiconductor structure 300 further include source/drain features 320N-1 to 320N-5 (may be collectively referred to as source/drain features 320N) and source/drain features 320P-1 to 320P-5 (may be collectively referred to as source/drain features 320P) in the source/drain regions of the active areas 302. The source/drain features 320N are disposed on opposite sides of the respective gate structure 304 and connected by the nanostructures 306 to form n-type transistor (e.g., the transistors NT1 to NT4). Similarly, the source/drain features 320P are disposed on opposite sides of the respective gate structure 304 and connected by the nanostructures 306 to form p-type transistor (e.g., the transistors PT1 to PT4). In some aspects, the source/drain features 320N and 320P are disposed on opposite sides of the respective nanostructures 306. More specifically, the source/drain features 320N and 320P are attached and electrically connected to the nanostructures 306 in the X-direction, as shown in FIGS. 4B and 4C. Furthermore, every two adjacent transistors in the X-direction share one source/drain feature 320N/320P, as shown in FIGS. 4C and 4D.

The source/drain features 320N and 320P may be formed by using an epitaxial growth process. In some embodiments, the source/drain features 320N may include epitaxially-grown material selected from a group consisting of SiP, SiC, SiPC, SiAs, Si, or a combination thereof. In some embodiments, the epitaxially-grown material of the source/drain features 320N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 320N for n-type transistors may be respectively referred to as n-type features and n-type source/drain features.

In some embodiments, the source/drain features 320P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 320P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 320P for p-type transistors may be respectively referred to as p-type source/drain features.

Referring to FIGS. 4A to 4F, the semiconductor structure 300 further include source/drain contacts 322-1 to 322-8 (may be collectively referred to as source/drain contacts 322) in a contact etch stop layer (CESL) 324, an inter-layer dielectric (ILD) layer 326 over the CESL 324, a CESL 328 over the ILD layer 326, and an ILD layer 330 over the CESL 328. As shown in FIGS. 4A to 4F, the source/drain contacts 322 extend lengthwise in the Y-direction. The source/drain contacts 322 are self-aligned source/drain contacts. This means that the source/drain contacts 322 are formed by using the gate spacers 316 as mask. Therefore, the source/drain contacts 322 are in direct contact with the gate spacers 316, as shown in FIGS. 4C and 4D. In some embodiments, the gate spacers 316 are trimmed due to the gate spacers 316 serving as the mask for forming the source/drain contacts 322. Therefore, the thickness of the gate spacers 316 in the X-direction is less than the thickness of the inner spacers 318 in the X-direction, as discussed above. In some embodiments, the source/drain contacts 322 are may also be referred to as front-side source/drain contacts.

As shown in FIG. 4A, in the top view, the source/drain contact 322-1 is adjacent to the gate structure 304-1 (or is adjacent to the transistor PT1) in the X-direction; the source/drain contact 322-2 is between the gate structures 304-2 and 304-3 (or between the transistors PT2 and NT3) in the X-direction; the source/drain contact 322-3 is adjacent to the gate structure 304-4 (or is adjacent to the transistor PT4) in the X-direction; the source/drain contact 322-6 is adjacent to the gate structure 304-1 (or is adjacent to the transistor NT1) in the X-direction; the source/drain contact 322-7 is between the gate structures 304-2 and 304-3 (or between the transistors NT2 and NT3) in the X-direction; and the source/drain contact 322-8 is adjacent to the gate structure 304-4 (or is adjacent to the transistor NT2) in the X-direction. Furthermore, in the top view, the source/drain contact 322-4 is between the gate structures 304-1 and 304-2 (or between the transistors PT1 and PT2, or between the transistors NT1 and NT2); and the source/drain contact 322-5 is between the gate structures 304-3 and 304-4 (or between the transistors PT3 and PT4, or between the transistors NT3 and NT4), as shown in FIG. 4A. In some aspects, the source/drain contacts 322-1, 322-3, 322-6, and 322-8 each is between one dielectric gate structure 314 and one gate structure 304, as shown in FIG. 4A.

Furthermore, each of the source/drain contacts 322 is over and in contact with top surfaces of the respective source/drain features 320N/320P. More specifically, each of the source/drain contacts 322 is over and electrically connected to the respective source/drain features 320N/320P. Specifically, as shown in FIGS. 4A to 4F, the source/drain contact 322-1 is over and electrically connected to the source/drain feature 320P-1 of the transistor PT1; the source/drain contact 322-2 is over and electrically connected to the source/drain feature 320P-3 shared by the transistors PT2 and PT3; the source/drain contact 322-3 is over and electrically connected to the source/drain feature 320P-5 of the transistor PT4; the source/drain contact 322-6 is over and electrically connected to the source/drain feature 320N-1 of the transistor NT1; the source/drain contact 322-7 is over and electrically connected to the source/drain feature 320N-3 shared by the transistors NT2 and NT3; and the source/drain contact 322-8 is over and electrically connected to the source/drain feature 320N-5 of the transistor NT4. Furthermore, the source/drain contact 322-4 is over and electrically connected to the source/drain feature 320P-2 shared by the transistors PT1 and PT2 and the source/drain feature 320N-2 shared by the transistors NT1 and NT2, and the source/drain contact 322-5 is over and electrically connected to the source/drain feature 320P-4 shared by the transistors PT3 and PT4 and the source/drain feature 320N-4 shared by the transistors NT3 and NT4, as shown in FIGS. 4A to 4F.

The source/drain contacts 322 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 322 may each include a single conductive material layer or multiple conductive layers.

As shown in FIGS. 4E and 4F, the CESL 324 is conformally formed on the sidewalls of the gate spacers 316 and the source/drain features 320P and 320N. The ILD layer 326 is over the CESL 136 to fill a remaining space between (or inside) the CESL 324, between the gate spacers 122, and between the source/drain features 320P and 320N. Furthermore, the CESL 328 is formed over the ILD layer 326, and the ILD layer 330 is formed over the CESL 328. The source/drain contacts 322 also pass through the ILD layer 330, the CESL 328, the ILD layer 326, and the CESL 324 to be in contact with and electrically connected to the source/drain features 320P or 320M, as shown in FIGS. 4E and 4F.

The CESLs 324 and 328 include a material that is different than ILD layers 326 and 330. The CESLs 324 and 328 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layers 326 and 330 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The front-side interconnection structure is over the device region (including transistors PT1 to PT4 and NT1 to NT4 and source/drain contacts 322) or at the front-side of the device region. As shown in FIGS. 4A to 4F, the semiconductor structure 300 further includes a front-side interconnection structure 402 including gate vias 404, vias 406 (including vias 406-1 to 406-8), metal conductors 408 (including metal conductors 408-1 to 408-6), a CESL 410, an ILD layer 412, a CESL 414, and an inter-metal dielectric (IMD) layer 416, which are over (or at the front-side of) the transistors PT1 to PT4 and NT1 to NT4. The gate vias 404, the vias 406, the metal conductors 408, the ILD layer 412, the CESLs 410 and 414, and the IMD layer 416 may also be referred to as front-side gate vias, front-side vias, front-side metal conductors, front-side ILD layer, front-side CESLs, and front-side IMD layers, respectively.

As shown in FIGS. 4A to 4F, the metal conductors 408 are in the CESL 414 and the IMD layer 416 and extend lengthwise in the X-direction. Each of the gate vias 404 in the ILD layer 412 is vertically between and electrically connected to the respective gate structure 304 and the respective metal conductor 408 (not shown). Each of the vias 406 in the CESL 410 and the ILD layer 412 is vertically between and electrically connected to the respective source/drain contact 322 and the respective metal conductor 108, as shown in FIGS. 4C to 4F. In some embodiments, the gate vias 404 and the vias 406 may have a square shape in the top view, as shown in FIG. 4A. In other embodiments, the gate vias 404 and the vias 406 may have circular shape in the top view.

The gate vias 404, the vias 406-4 and 406-5, and the metal conductors 408-1, 408-2, 408-3, and 408-4 are used for connections of the transistors (e.g., the transistors PT1 to PT4 and NT1 to NT4) or the circuit cell in the semiconductor structure 300. As shown in FIGS. 4A, 4E, and 4F, the gate vias 404 connects the gate structure 304-1, 304-2, 304-3, and 304-4 to the metal conductor 408-3. The vias 406-4 and 406-5 respectively connect the source/drain contacts 322-4 and 322-5 to the metal conductor 508-1. Although not shown in FIGS. 4A to 4F, the metal conductors 408-2 and 408-4 are connected to the other circuit cells. In some embodiments, the metal conductors 408-2 to 408-5 are between the metal conductors 408-1 and 408-6 in the Y-direction, as shown in FIGS. 4A, 4E, and 4F.

As shown in FIGS. 4A to 4F, the metal conductor 408-1 serves as VDD line that is electrically coupled to a voltage source (not shown) (e.g., the supply voltage VDD) and electrically connected to the source/drain features 320P-1, 320P-3, and 320P-5 to supply VDD voltage to the transistors PT1 to PT4. As shown in FIGS. 4A to 4F, the vias 406-1, 406-2, and 406-3 are over and electrically connected to the source/drain contacts 322-1, 322-2, and 322-3, respectively. More specifically, the vias 406-1, 406-2, and 406-3 are respectively over and in contact with top surfaces of the source/drain contacts 322-1, 322-2, and 322-3. The metal conductor 408-1 is over and electrically connected to the vias 406-1, 406-2, and 406-3. As such, the metal conductor 408-1 is electrically connected to the source/drain feature 320P-1 of the transistor PT1 through the via 406-1 and the source/drain contact 322-1, electrically connected to the source/drain feature 320P-3 shared by the transistors PT2 and PT3 through the via 406-2 and the source/drain contact 322-2, and electrically connected to the source/drain feature 320P-5 of the transistor PT4 through the via 406-3 and the source/drain contact 322-3, as shown in FIGS. 4A to 4F. Therefore, VDD voltage is supplied to the source/drain feature 320P-1 of the transistor PT1, the source/drain feature 320P-3 shared by the transistors PT2 and PT3, and the source/drain feature 320P-5 of the transistor PT4. In some embodiments, the metal conductor 408-1 may be referred to as the (front-side) VDD conductor or the (front-side) VDD line.

As shown in FIGS. 4A to 4F, the metal conductor 408-6 serves as VSS line that is electrically coupled to a voltage source (not shown) (e.g., the supply voltage VSS (or ground)) and electrically connected to the source/drain features 320N-1, 320N-3, and 320N-5 to supply VSS voltage (or ground voltage) to the transistors NT1 to NT4. As shown in FIGS. 4A to 4F, the vias 406-6, 406-7, and 406-8 are over and electrically connected to the source/drain contacts 322-6, 322-7, and 322-8, respectively. More specifically, the vias 406-6, 406-7, and 406-8 are respectively over and in contact with top surfaces of the source/drain contacts 322-6, 322-7, and 322-8. The metal conductor 408-6 is over and electrically connected to the vias 406-6, 406-7, and 406-8. As such, the metal conductor 408-6 is electrically connected to the source/drain feature 320N-1 of the transistor NT1 through the via 406-6 and the source/drain contact 322-6, electrically connected to the source/drain feature 320N-3 shared by the transistors NT2 and NT3 through the via 406-7 and the source/drain contact 322-7, and electrically connected to the source/drain feature 320N-5 of the transistor NT4 through the via 406-8 and the source/drain contact 322-8, as shown in FIGS. 4A to 4F. Therefore, VSS voltage is supplied to the source/drain feature 320N-1 of the transistor NT1, the source/drain feature 320N-3 shared by the transistors NT2 and NT3, and the source/drain feature 320N-5 of the transistor NT4. In some embodiments, the metal conductor 408-6 may be referred to as the (front-side) VSS conductor or the (front-side) VSS line.

The back-side interconnection structure is under the device region (including transistors PT1 to PT4 and NT1 to NT4 and source/drain contacts 322) or at the back-side of the device region. As shown in FIGS. 4A to 4F, the semiconductor structure 300 further includes a back-side interconnection structure 502 including source/drain contacts 504 (including source/drain contacts 504-1 to 504-7) and metal conductors 506 (including metal conductors 506-1 and 506-2), a dielectric layer 508, a CESL 510, and an IMD layer 512, which are under (or at the back-side of) the transistors PT1 to PT4 and NT1 to NT4. The source/drain contacts 504, the metal conductors 506, the dielectric layer 508, the CESL 510, and the IMD layer 512 may also be referred to as back-side source/drain contacts, back-side metal conductors, back-side dielectric layer, back-side CESL, and back-side IMD layer, respectively.

As shown in FIGS. 4C to 4F, source/drain contacts 504-1 to 504-7 are disposed in the dielectric layer 508. As shown in FIGS. 4B to 4F, the source/drain contacts 504 extend lengthwise in the Y-direction. As shown in FIG. 4B, in the top view, the source/drain contact 504-1 is adjacent to the gate structure 304-1 (or is adjacent to the transistor PT1) in the X-direction; the source/drain contact 504-2 is between the gate structures 304-2 and 304-3 (or between the transistors PT2 and NT3) in the X-direction; the source/drain contact 504-3 is adjacent to the gate structure 304-4 (or is adjacent to the transistor PT4) in the X-direction; the source/drain contact 504-5 is adjacent to the gate structure 304-1 (or is adjacent to the transistor NT1) in the X-direction; the source/drain contact 504-6 is between the gate structures 304-2 and 304-3 (or between the transistors NT2 and NT3) in the X-direction; and the source/drain contact 504-7 is adjacent to the gate structure 304-4 (or is adjacent to the transistor NT2) in the X-direction. Furthermore, in the top view, the source/drain contact 504-4 is between the gate structures 304-1 and 304-2 (or between the transistors PT1 and PT2, or between the transistors NT1 and NT2), as shown in FIG. 4B. In some aspects, the source/drain contacts 504-1, 504-3, 504-5, and 504-7 each is between one dielectric gate structure 314 and one gate structure 304, as shown in FIG. 4B.

Furthermore, each of the source/drain contacts 504 is under and in contact with bottom surfaces of the respective source/drain features 320N/320P. More specifically, each of the source/drain contacts 504 is under and electrically connected to the respective source/drain features 320N/320P. Specifically, as shown in FIGS. 4A to 4F, the source/drain contact 504-1 is under and electrically connected to the source/drain feature 320P-1 of the transistor PT1; the source/drain contact 504-2 is under and electrically connected to the source/drain feature 320P-3 shared by the transistors PT2 and PT3; the source/drain contact 504-3 is under and electrically connected to the source/drain feature 320P-5 of the transistor PT4; the source/drain contact 504-5 is under and electrically connected to the source/drain feature 320N-1 of the transistor NT1; the source/drain contact 504-6 is under and electrically connected to the source/drain feature 320N-3 shared by the transistors NT2 and NT3; and the source/drain contact 504-7 is under and electrically connected to the source/drain feature 320N-5 of the transistor NT4. Furthermore, the source/drain contact 504-4 is under and electrically connected to the source/drain feature 320P-2 shared by the transistors PT1 and PT2 and the source/drain feature 320N-2 shared by the transistors NT1 and NT2, as shown in FIGS. 4A to 4F.

The source/drain contacts 504 may each include a conductive material such as Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 504 may each include a single conductive material layer or multiple conductive layers.

As shown in FIGS. 4A to 4F, the metal conductors 506 are in the CESL 510 and the IMD layer 512 and extend lengthwise in the X-direction. As shown in FIGS. 4A to 4F, the metal conductor 506-1 serves as VDD line that is electrically coupled to a voltage source (not shown) (e.g., the supply voltage VDD) and electrically connected to the source/drain features 320P-1, 320P-3, and 320P-5 to supply VDD voltage to the transistors PT1 to PT4. The metal conductor 506-1 is under and electrically connected to the source/drain contacts 504-1, 504-2, and 504-3. As such, the metal conductor 506-1 is electrically connected to the source/drain feature 320P-1 of the transistor PT1 through the source/drain contact 504-1, electrically connected to the source/drain feature 320P-3 shared by the transistors PT2 and PT3 through the source/drain contact 504-2, and electrically connected to the source/drain feature 320P-5 of the transistor PT4 through the source/drain contact 504-3, as shown in FIGS. 4A to 4F. Therefore, VDD voltage is supplied to the source/drain feature 320P-1 of the transistor PT1, the source/drain feature 320P-3 shared by the transistors PT2 and PT3, and the source/drain feature 320P-5 of the transistor PT4. In some embodiments, the metal conductor 506-1 may be referred to as the (back-side) VDD conductor or the (back-side) VDD line.

As shown in FIGS. 4A to 4F, the metal conductor 506-2 serves as VSS line that is electrically coupled to a voltage source (not shown) (e.g., the supply voltage VSS (or ground)) and electrically connected to the source/drain features 320N-1, 320N-3, and 320N-5 to supply VSS voltage (or ground voltage) to the transistors NT1 to NT4. The metal conductor 506-6 is under and electrically connected to the source/drain contacts 504-5, 504-6, and 504-7. As such, the metal conductor 506-2 is electrically connected to the source/drain feature 320N-1 of the transistor NT1 through the source/drain contact 504-5, electrically connected to the source/drain feature 320N-3 shared by the transistors NT2 and NT3 through the source/drain contact 504-6, and electrically connected to the source/drain feature 320N-5 of the transistor NT4 through the source/drain contact 504-7, as shown in FIGS. 4A to 4F. Therefore, the VSS voltage is supplied to the source/drain feature 320N-1 of the transistor NT1, the source/drain feature 320N-3 shared by the transistors NT2 and NT3, and the source/drain feature 320N-5 of the transistor NT4. In some embodiments, the metal conductor 506-2 may be referred to as the (back-side) VSS conductor or the (back-side) VSS line.

The CESLs 410, 414, and 510 include a material that is different than the dielectric layer 508 and the ILD layer 412, 416, and 512. The CESLs 410, 414, and 510 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The dielectric layer 508 and the ILD layer 412, 416, and 512 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or a combination thereof.

The materials of the source/drain contacts 322, the gate vias 404, the vias 406, the metal conductors 408, the source/drain contacts 504, and the metal conductors 506 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof.

In the present embodiments, the source/drain feature 320P-2 of (or shared by) the transistors PT1 and PT2 and the source/drain feature 320N-2 of (or shared by) the transistors NT1 and NT2 are electrically connected with each other not only through the (front-side) source/drain contact 322-4 but also through the (back-side) source/drain contact 504-4. Therefore, the resistance of such local connection of the source/drain feature 320P-2 of the transistor PT1 and the source/drain feature 320N-2 of the transistor NT1 may be reduced.

As discussed above, the source/drain contact 504-4 is used for local connection of the source/drain feature 320P-2 and 320N-2. Therefore, the metal conductor 506-1 serving as VDD line and the metal conductor 506-2 serving as VSS line are electrically isolated from the source/drain contact 504-4. As shown in FIGS. 4B to 4F, in the top view, each of the metal conductor 506-1 serving as VDD line and the metal conductor 506-2 serving as VSS line has two elongated portions 506e and a jog portion 506j, in which the jog portion 506j is between the elongated portions 506e in the X-direction. In some embodiments, the elongated portions 506e of the metal conductors 506-1 and 506-2 are separated from the source/drain contact 504-4 in the X-direction in the top view, as shown in FIG. 4B. Furthermore, as shown in FIG. 4B, the jog portions 506j of the metal conductors 506-1 and 506-2 are separated from the source/drain contact 504-4 in the Y-direction in the top view. In some embodiments, each of the jog portions 506j is separated from the source/drain contact 504-4 in the Y-direction by a distance that is greater than about 4 nm. If the jog portions 506j are separated from the source/drain contact 504-4 in the Y-direction by less than 4 nm, the isolation between the metal conductors 506-1 and 506-2 and the source/drain contact 504-4 may be impacted.

In some embodiments, in the top view, the elongated portions 506e of the metal conductors 506-1 overlap the active area 302-1, and the elongated portions 506e of the metal conductors 506-2 overlap the active area 302-2, as shown in FIG. 4B. However, in the top view, the jog portion 506j of the metal conductors 506-1 separated from the active area 302-1 in the Y-direction and the jog portion 506j of the metal conductors 506-1 separated from the active area 302-1 in the Y-direction, as shown in FIG. 4B. Therefore, the metal conductors 506-1 and 506-2 respectively detours around the source/drain contact 504-4 in the top view, as shown in FIG. 4B. Furthermore, as shown in FIG. 4B, edges 506je of the jog portion 506j of the metal conductors 506-1 and 506-2 extending in the X-direction are offset from edges 506ee of the elongated portions 506e of the metal conductors 506-1 and 506-2 extending in the X-direction by a distance in the Y-direction, in accordance with some embodiments.

In the present embodiments, the space at the back-side of the circuit cells 402-1 and 402-2 is completely used for the metal conductors 606-1 and 606-2, so that the metal conductors 606-1 and 606-2 may have the widest width in the Y-direction, thereby having lowest metal resistance in the semiconductor structure 300. As shown in FIGS. 4A to 4F, the metal conductors 408-1 and 506-1 serving as the VDD lines are electrically connected to the same source/drain features 320P of the transistors PT1 to PT4, and the metal conductors 408-1 and 506-1 serving as the VSS lines are electrically connected to the same source/drain features 320N of the transistors NT1 to NT4. Therefore, the transistors PT1 to PT4 and NT1 to NT4 are supplied with VDD voltage and VSS voltage from both front-side and back-side of the semiconductor structure 300, thereby improving the reliability of the semiconductor structure 300. This may also be seen as the metal conductors 408-1 and 506-1 serving as the VDD lines are electrically connected with each other and the metal conductors 408-6 and 506-2 serving as the VSS lines are electrically connected with each other. Therefore, the metal conductors 408-1 and 506-1 are electrically connected with each other in parallel and the metal conductors 408-6 and 506-2 are electrically connected with each other in parallel. This may also reduce the total resistance of the metal conductors.

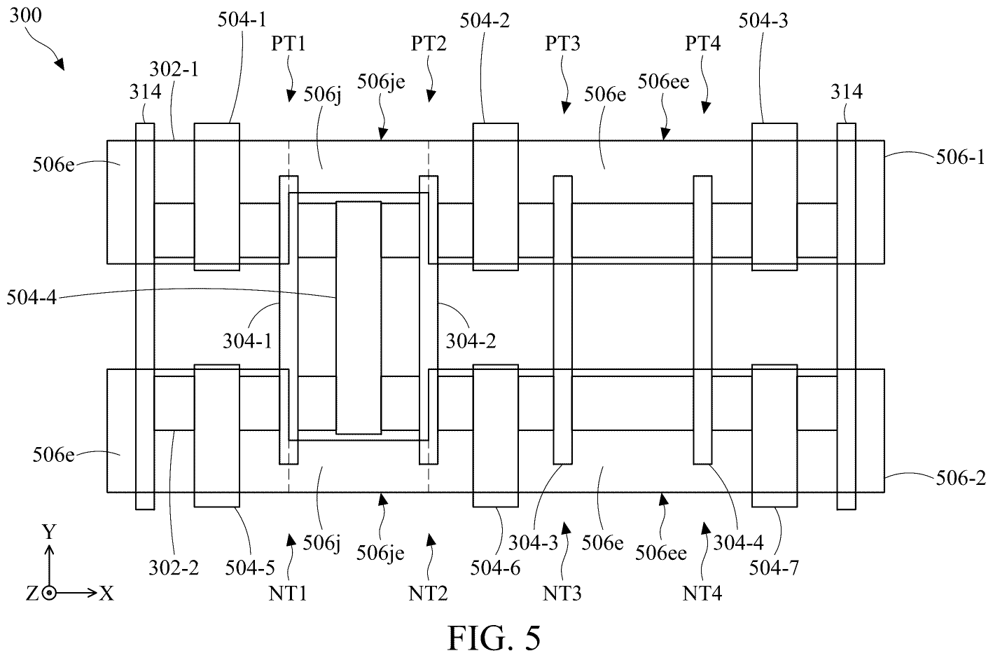

FIG. 5 is a top view (or a layout) of the semiconductor structure 300 in the logic region 20 of the IC chip 10, in accordance with some alternative embodiments of the present disclosure, in which FIG. 5 illustrates the features in the device region and the back-side interconnection structure. The semiconductor structure 300 shown in FIG. 5 is similar to the semiconductor structure 300 shown in FIG. 4B, except that the jog portions 506j of the metal conductors 506-1 and 506-2 shown in FIG. 5 have a narrower width in the Y-direction.

Referring back to the FIG. 4B, as discussed above, the edges 506je of the jog portion 506j of the metal conductors 506-1 and 506-2 extending in the X-direction are offset from the edges 506ee of the elongate portions 506e of the metal conductors 506-1 and 506-2 extending in the X-direction by a distance in the Y-direction. In other words, the jog portions 506j are protruded from the metal conductors 506-1 and 506-2, as shown in FIG. 4B. Such protrusion may reduce the resistance of the metal conductors 506-1 and 506-2.

In some embodiments, as shown in FIG. 5, the edges 506je of the jog portion 506j of the metal conductors 506-1 and 506-2 extending in the X-direction are aligned with the edges 506ee of the elongate portions 506e of the metal conductors 506-1 and 506-2 extending in the X-direction. Such metal conductors 506-1 and 506-2 without protrusion may avoid disturbing or affecting the layouts of other metal conductors.

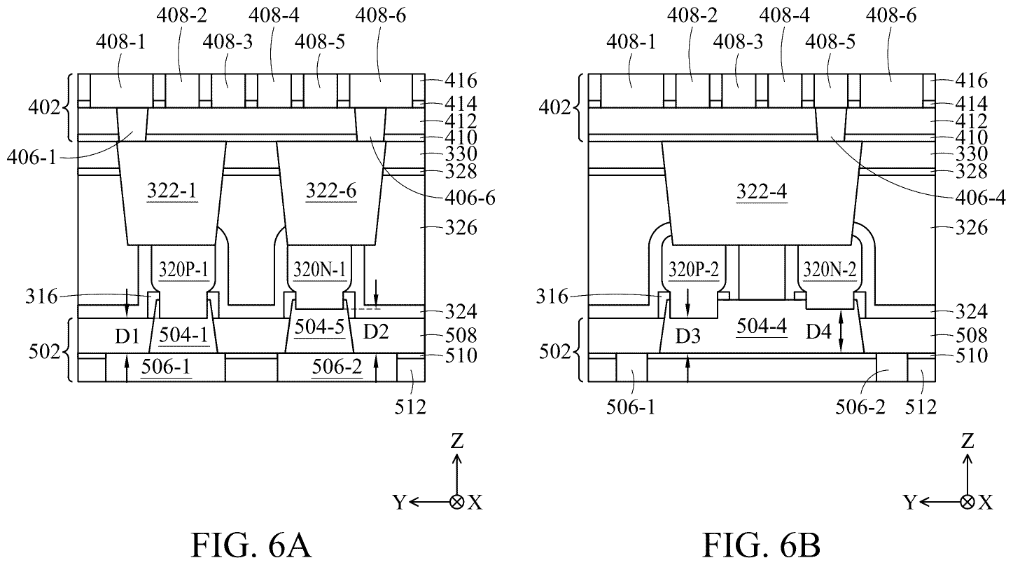

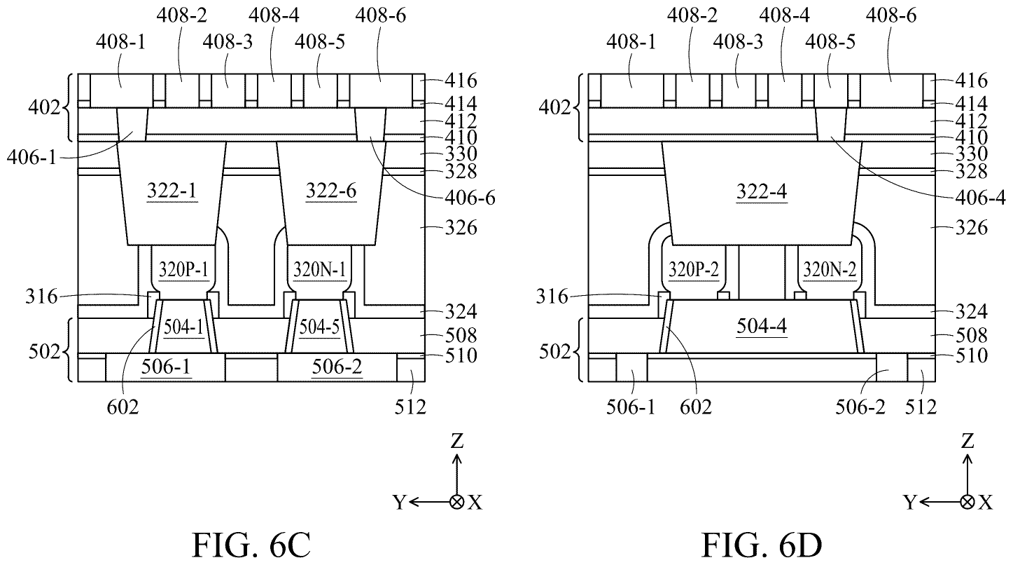

FIGS. 6A and 6B are Y-Z cross-sectional views of the semiconductor structure 300 along the lines C-C′ and D-D′ of FIGS. 4A and 4B, respectively, in accordance with some alternative embodiments of the present disclosure. The semiconductor structure 300 shown in FIGS. 6A and 6B are similar to the semiconductor structure 300 shown in FIGS. 4E and 4F, except that the source/drain contacts 504 shown in FIGS. 6A and 6B have a different shape than that the source/drain contacts 504 shown in FIGS. 4E and 4F. In some embodiments, the source/drain features 320P and 320N have different compositions, materials, and/or dopants. Therefore, the source/drain features 320P and 320N have different etch selectivity during the formation of the source/drain contacts 504. In some embodiments, the source/drain features 320P may have less recess during the formation of the source/drain contacts 504 to retain strain for improved hole mobility. In the result, a distance D4 between a bottom surface of the source/drain feature 320N-2 and a bottom surface of the source/drain contact 504-4 is greater than a distance D3 between a bottom surface of the source/drain feature 320P-2 and the bottom surface of the source/drain contact 504-4, as shown in FIG. 6B.

Furthermore, a distance D2 between a bottom surface of the source/drain feature 320N-1 and a bottom surface of the source/drain contact 504-5 is greater than a distance D1 between a bottom surface of the source/drain feature 320P-1 and the bottom surface of the source/drain contact 504-1, as shown in FIG. 6A. In these cases, the source/drain contact 504 is also in contact with sidewalls of the source/drain features 320N/320P. For examples, the source/drain contact 504-4 is also in contact with sidewalls of the source/drain features 320P-2 and 320N-2, the source/drain contact 504-5 is also in contact with sidewalls of the source/drain features 320P-2, and the source/drain contact 504-1 is also in contact with sidewalls of the source/drain features 320P-1. In some embodiments, the source/drain contact 504-4 in these embodiments has an asymmetric shape in the Y-Z cross-sectional view, as shown in FIG. 6B.

FIGS. 6C and 6D are Y-Z cross-sectional views of the semiconductor structure along the lines C-C′ and D-D′ of FIGS. 4A and 4B, respectively, in accordance with some alternative embodiments of the present disclosure. The semiconductor structure 300 shown in FIGS. 6C and 6D is similar to the semiconductor structure 300 shown in FIG. 4B, except that the semiconductor structure 300 shown in FIGS. 6C and 6D further includes dielectric layers 602 on sidewalls of the source/drain contacts 504. More specifically, the dielectric layers 602 fully surround (sidewalls of) the source/drain contacts 504. The dielectric layers 602 separate the source/drain contacts 504 from the dielectric layer 508 and the gate spacers 316. In some embodiments, the dielectric layers 602 include dielectric material having nitrogen-content, and the dielectric material selected from a group consist of Si₃N₄, SiON, SiOC, SiOCN, or a combination thereof. The dielectric layers 602 may further improve the isolation margin for the source/drain contacts 330A and 330B to the gate structures 304. The dielectric layers 602 may also be referred to as contact sidewall layers, in accordance with some alternative embodiments.

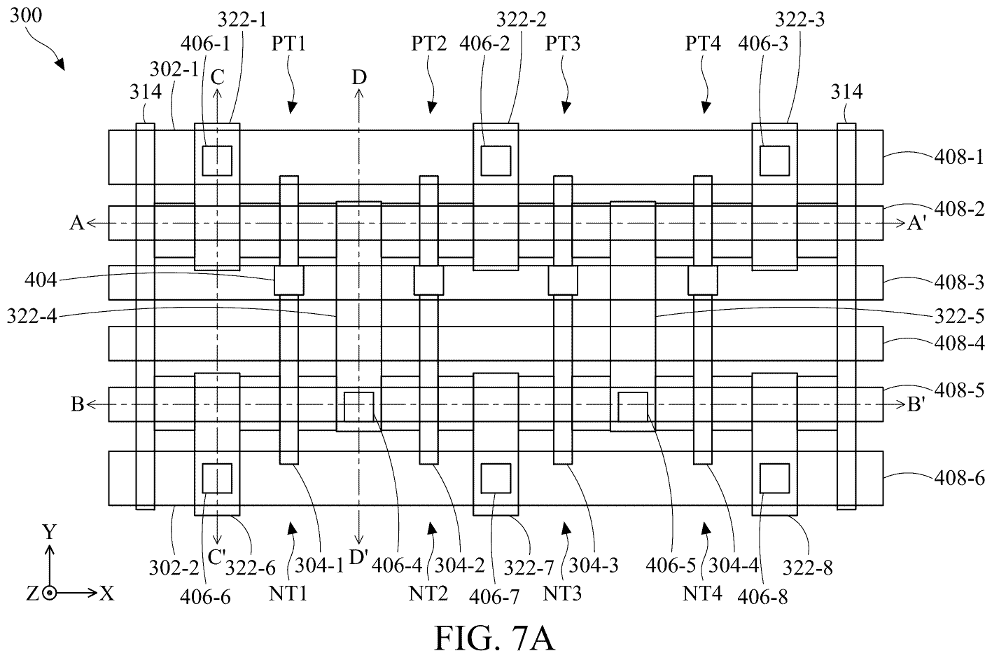

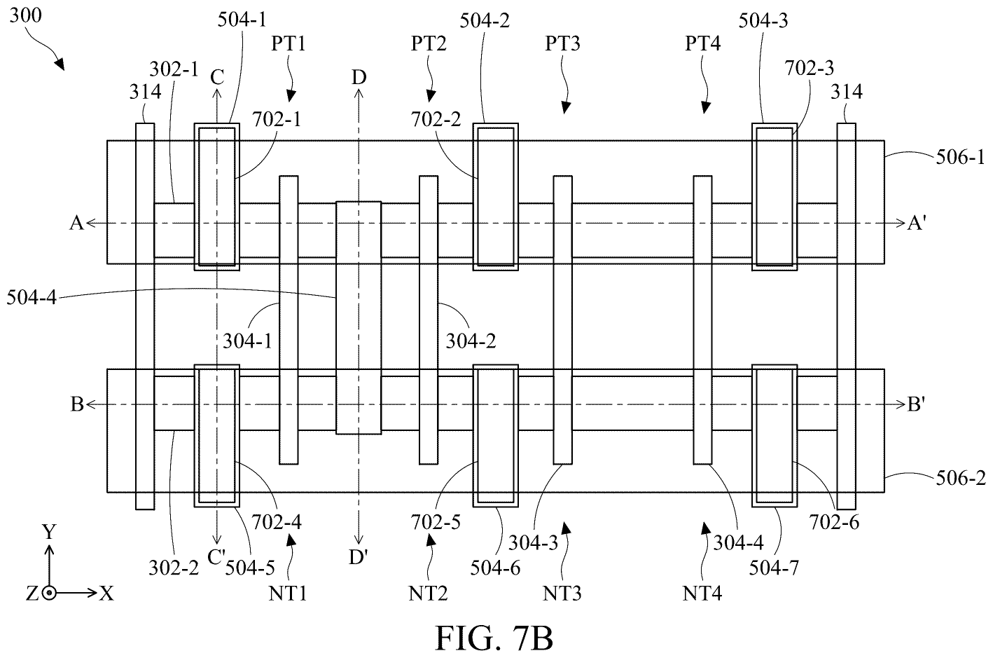

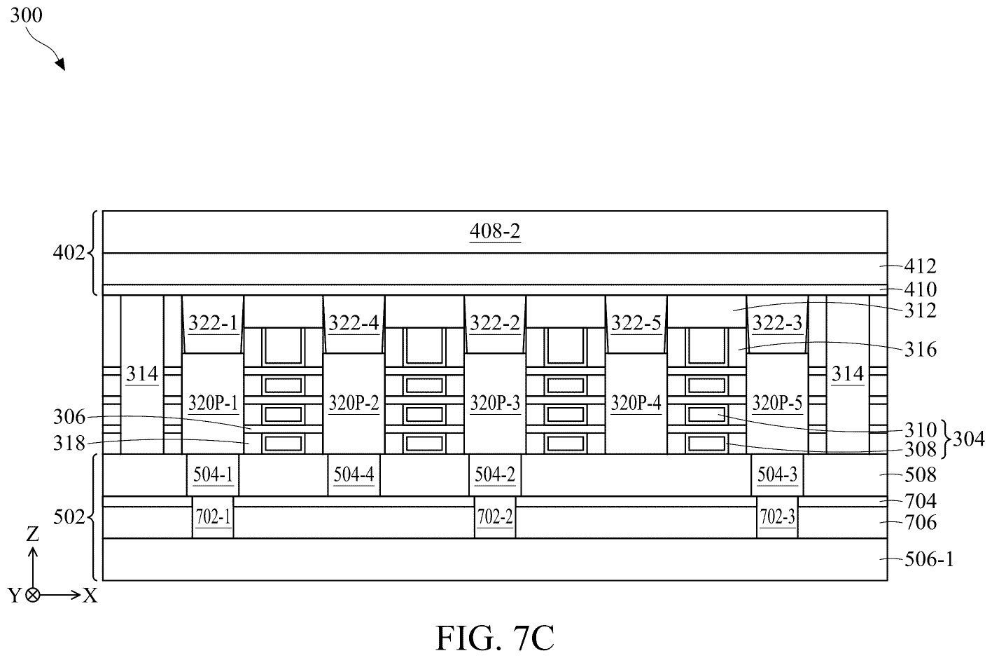

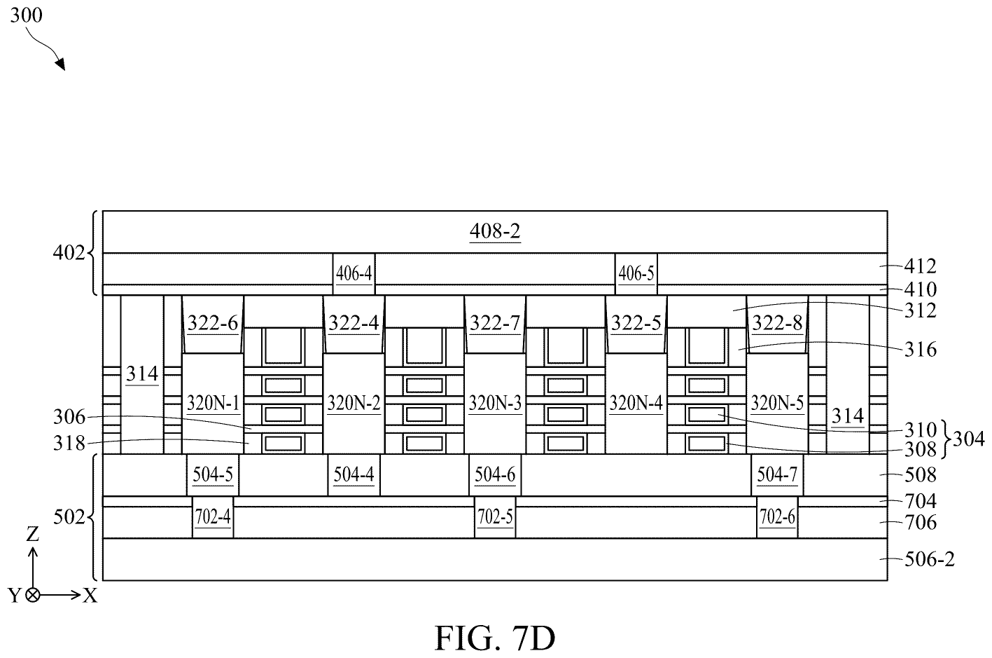

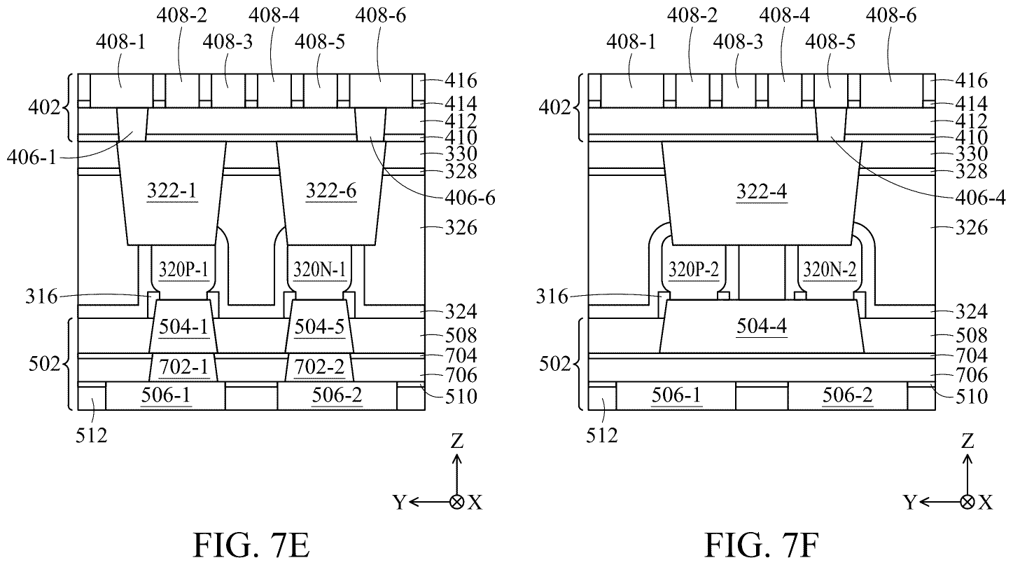

FIGS. 7A and 7B are top views (or layouts) of the semiconductor structure 300 in the logic region 20 of the IC chip 10, in accordance with some alternative embodiments of the present disclosure, in which FIG. 7A illustrates the features in the device region and the front-side interconnection structure, and FIG. 7B illustrates the features in the device region and the back-side interconnection structure.

FIG. 7C is an X-Z cross-sectional view of the semiconductor structure 300 along the line A-A′ in FIGS. 7A and 7B, in accordance with some alternative embodiments of the present disclosure. FIG. 7D is an X-Z cross-sectional view of the semiconductor structure 300 along the line B-B′ in FIGS. 7A and 7B, in accordance with some alternative embodiments of the present disclosure. FIG. 7E is a Y-Z cross-sectional view of the semiconductor structure 300 along the line C-C′ in FIGS. 7A and 7B, in accordance with some alternative embodiments of the present disclosure. FIG. 7F is a Y-Z cross-sectional view of the semiconductor structure 300 along the line D-D′ in FIGS. 7A and 7B, in accordance with some alternative embodiments of the present disclosure.

The semiconductor structure 300 shown in FIGS. 7A and 7F is similar to the semiconductor structure 300 shown in FIGS. 4A to 4F, except that the semiconductor structure 300 shown in FIGS. 7A and 7F further includes vias 702 (including vias 702-1, 702-2, 702-3, 702-4, 702-5, and 702-6), a CESL 704, and an IMD layer 706. The vias 702, the CESL 704, and the ILD layer 706 are disposed under (or at the back-side of) the transistors PT1 to PT4 and NT1 to NT4. The vias 702, the CESL 704, and the IMD layer 706 may also be referred to as back-side vias, back-side CESL, and back-side IMD layer, respectively. The materials of the vias 702, the CESL 704, and the IMD layer 706 are similar to the vias 406, the CESL 510, and the IMD layer 512.

As shown in FIGS. 7A to 7F, the vias 702 are in the CESL 704 and the IMD layer 706 and extend lengthwise in the Y-direction. Each of the vias 702 in the CESL 704 and the IMD layer 706 is vertically between and electrically connected to the respective source/drain contact 504 and the respective metal conductor 506, as shown in FIGS. 7A to 7F. In some embodiments, the vias 702 may have a rectangle shape in the top view, as shown in FIG. 7A. Furthermore, lengths of the vias 702 in the Y-direction are greater than lengths of the vias 406 in the Y-direction due to a wider space on the back-side of the semiconductor structure 300.

As shown in FIGS. 7A to 7F, the vias 702-1, 702-2, 702-3, 702-4, 702-5, and 702-6 are under and electrically connected to the source/drain contacts 504-1, 504-2, 504-3, 504-5, 504-6, and 504-7, respectively. The vias 702-1, 702-2, and 702-3 are over and electrically connected to the metal conductor 506-1, and the 702-4, 702-5, 702-6 are over and electrically connected to the metal conductor 506-2. In other words, the vias 702-1, 702-2, and 702-3 are respectively between and electrically connected to the source/drain contacts 504-1, 504-2, and 504-3 and the metal conductor 506-1, and the vias 702-4, 702-5, and 702-6 are respectively between and electrically connected to the source/drain contacts 504-5, 504-6, and 504-7 and the metal conductor 506-2, as shown in FIGS. 7A to 7F.

In the embodiments shown in FIGS. 7A to 7F, due to metal conductors 506-1 and 506-2 are disposed in lower layer than that shown in FIGS. 4A to 4C, the metal conductors 506-1 and 506-2 can be disposed directly under the source/drain contact 504-4 rather than detour around the source/drain contact 504-4 discussed above in the top view. Furthermore, in the top view, the metal conductors 506-1 and 506-2 are partially overlap the source/drain contact 504-4, as shown in FIG. 7B. In some embodiments, the metal conductors 506-1 and 506-2 fully overlap the active areas 302-1 and 302-2, respectively, as shown in FIG. 7B. Therefore, the vias 702 may further improve the isolation margin for the metal conductors 506-1 and 506-2 to the source/drain contact 504-4. Furthermore, the metal conductors 506-1 and 506-2 can be designed with wider width in the Y-direction for reducing resistance.

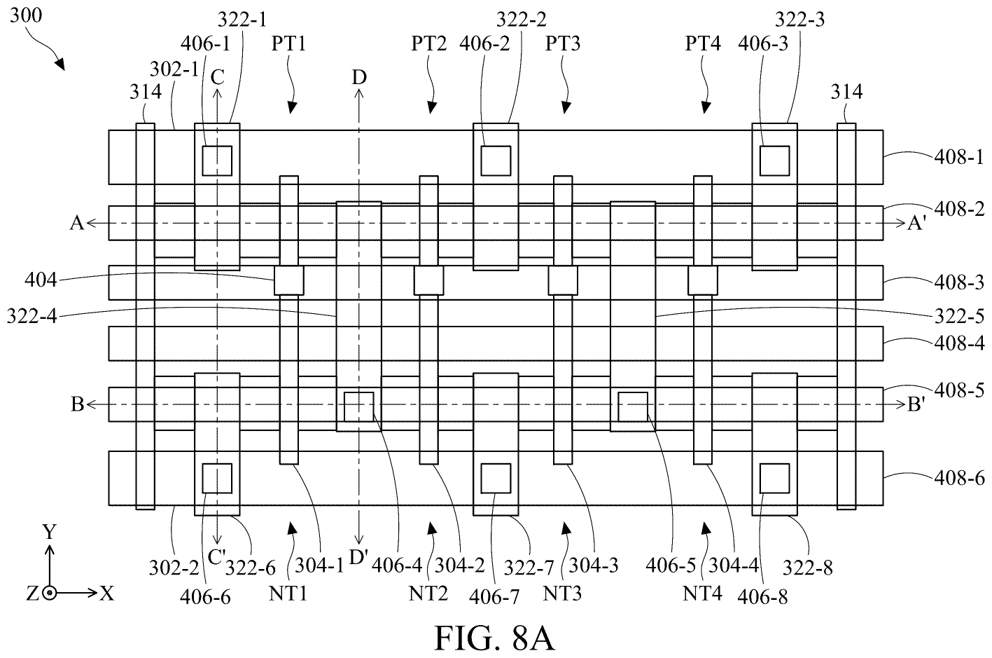

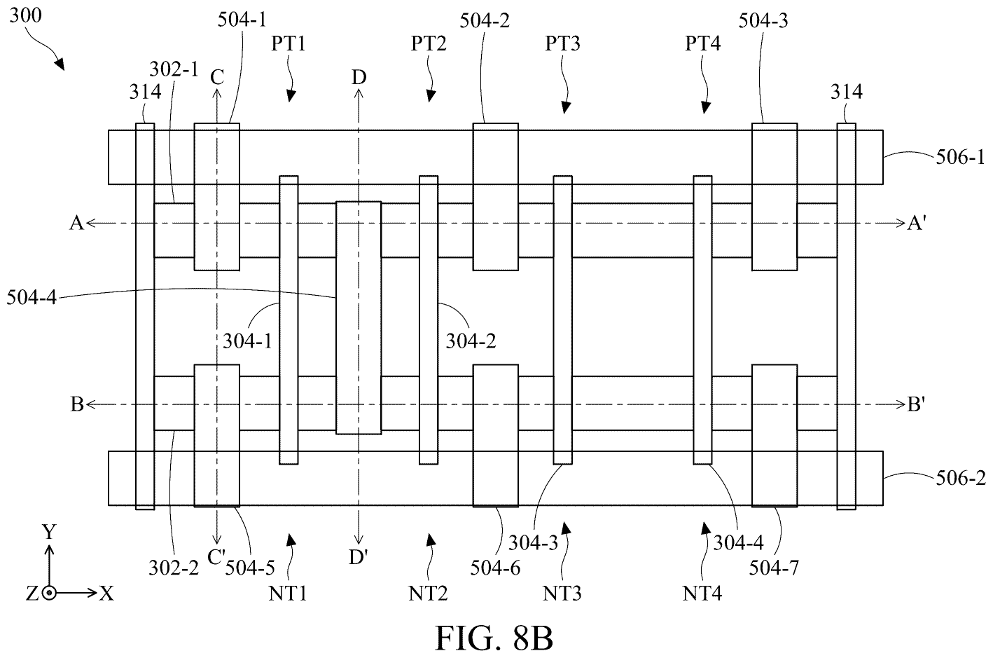

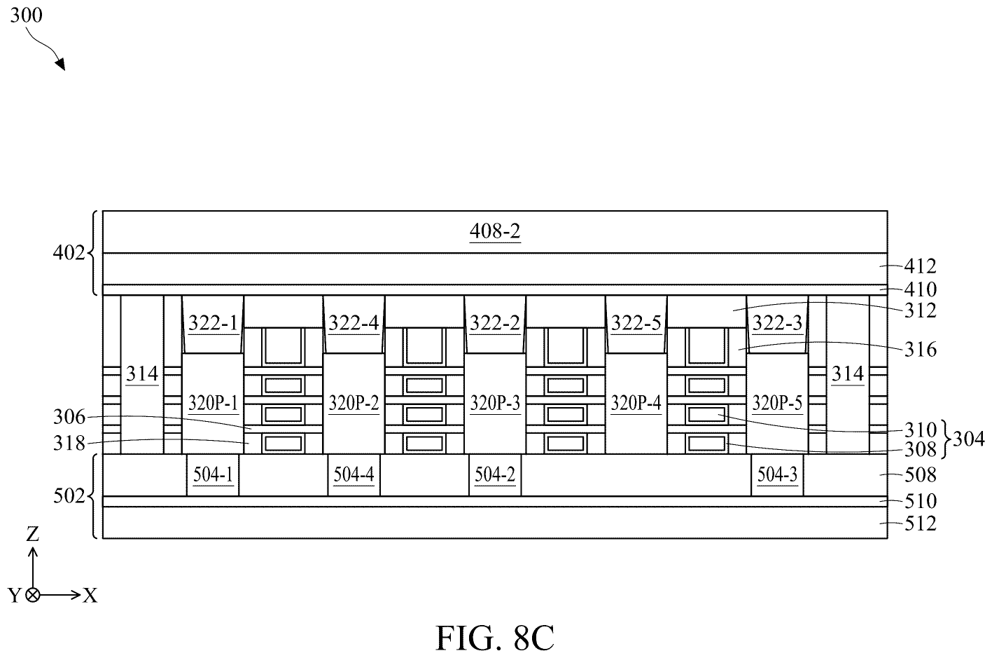

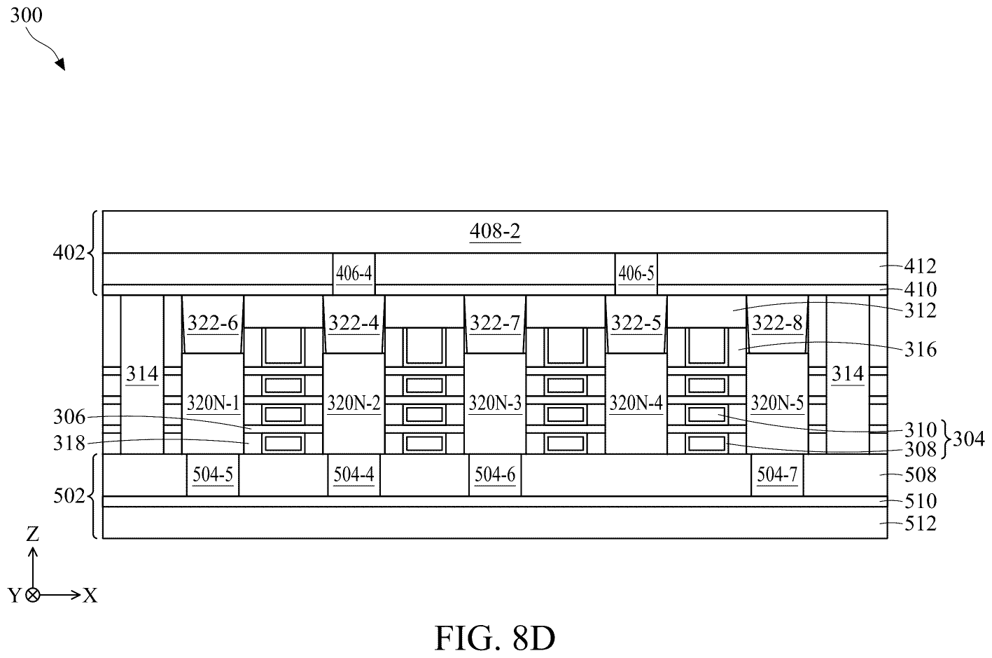

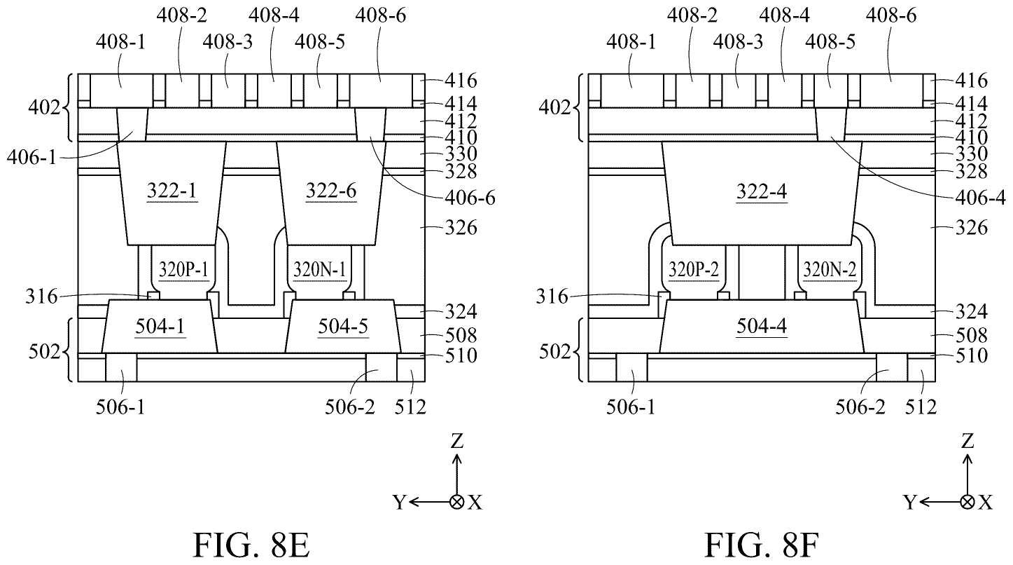

FIGS. 8A and 8B are top views (or layouts) of the semiconductor structure in the logic region of the IC chip, in accordance with some alternative embodiments of the present disclosure, in which FIG. 8A illustrates the features in the device region and the front-side interconnection structure, and FIG. 8B illustrates the features in the device region and the back-side interconnection structure.

FIG. 8C is an X-Z cross-sectional view of the semiconductor structure along the line A-A′ in FIGS. 8A and 8B, in accordance with some alternative embodiments of the present disclosure. FIG. 8D is an X-Z cross-sectional view of the semiconductor structure along the line B-B′ in FIGS. 8A and 8B, in accordance with some alternative embodiments of the present disclosure. FIG. 8E is a Y-Z cross-sectional view of the semiconductor structure along the line C-C′ in FIGS. 8A and 8B, in accordance with some alternative embodiments of the present disclosure. FIG. 8F is a Y-Z cross-sectional view of the semiconductor structure along the line D-D′ in FIGS. 8A and 8B, in accordance with some alternative embodiments of the present disclosure.

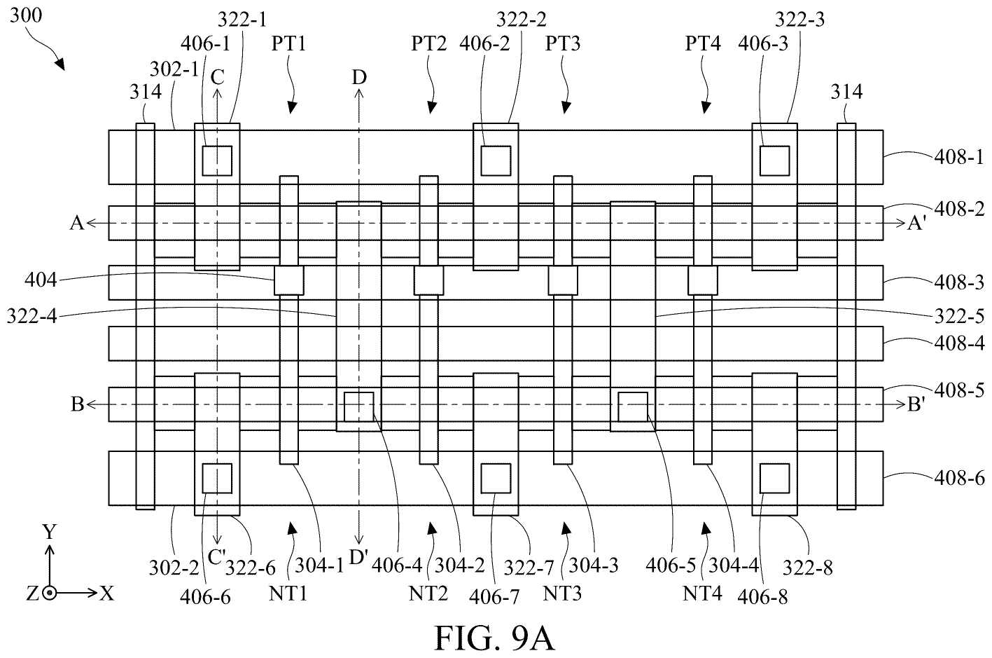

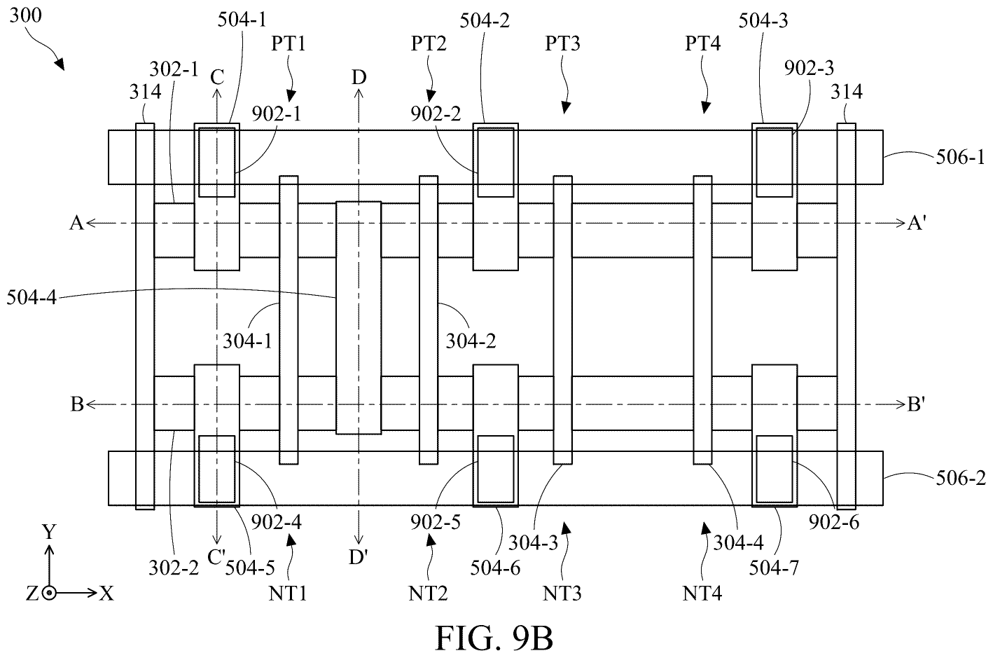

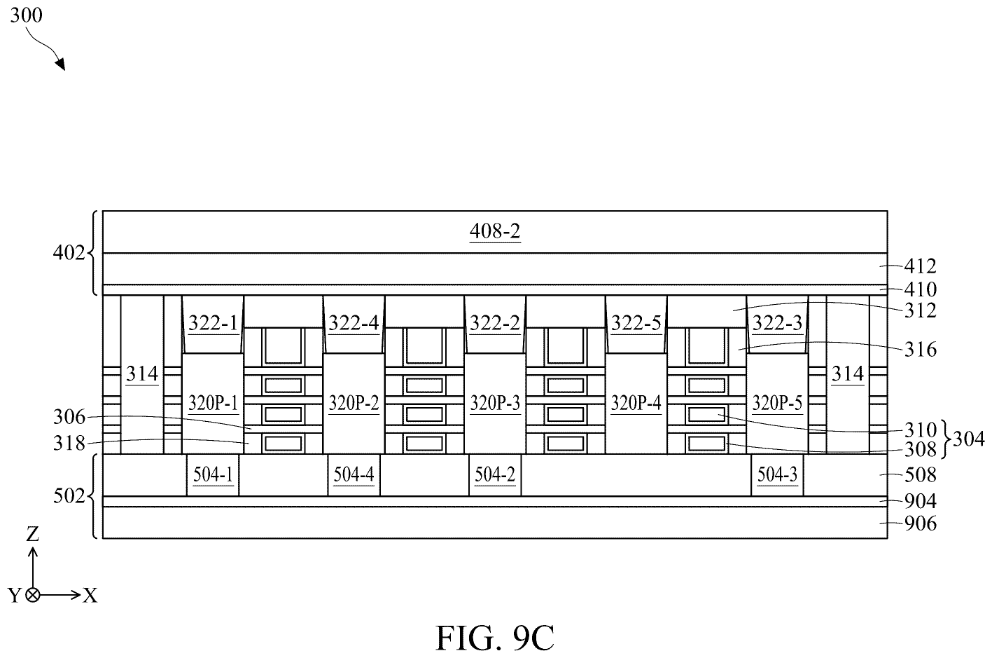

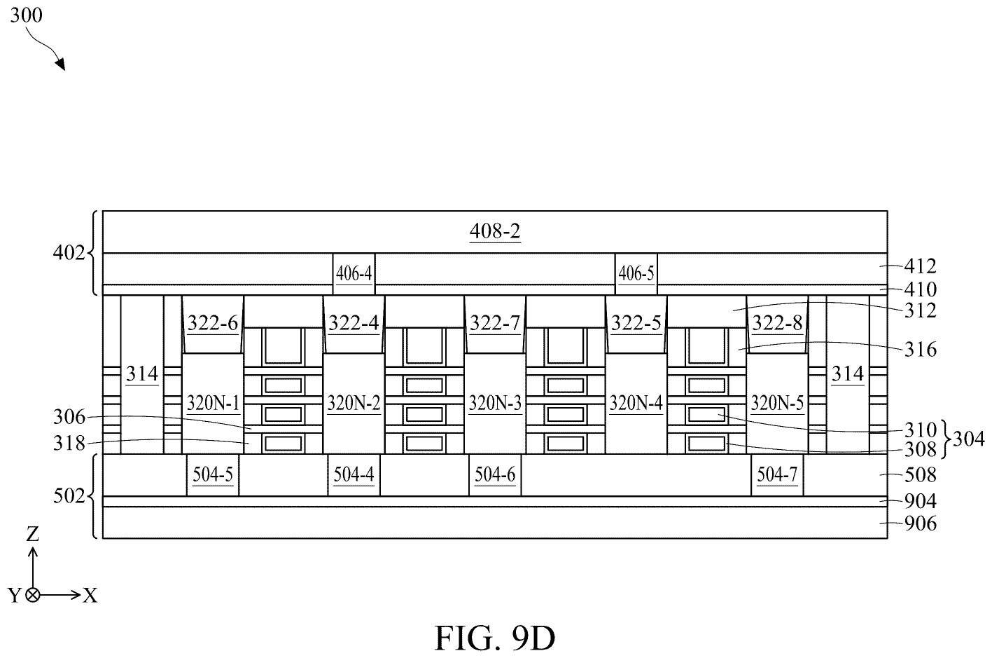

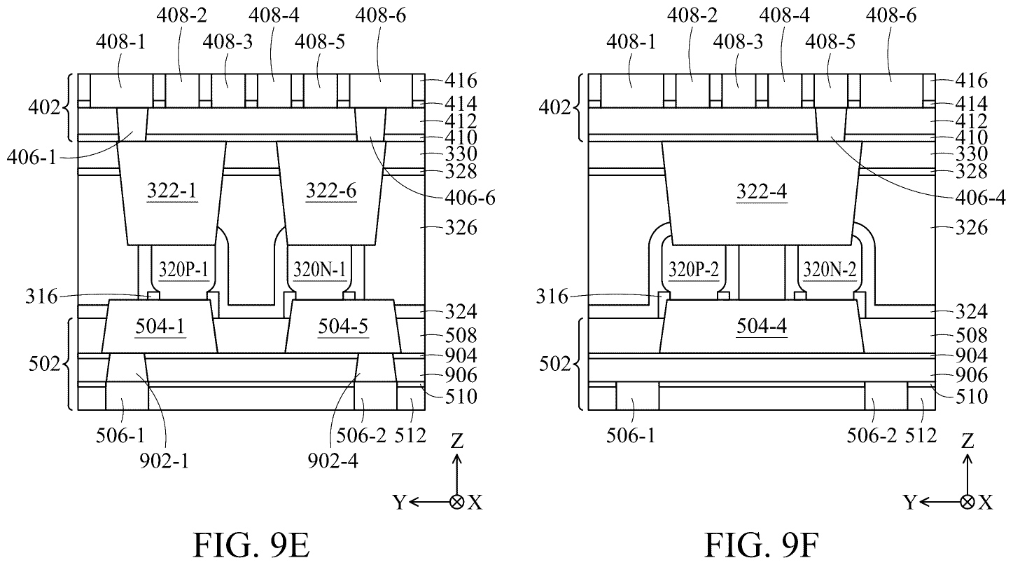

The semiconductor structure 300 shown in FIGS. 8A and 8F is similar to the semiconductor structure 300 shown in FIGS. 4A to 4F, except that the metal conductors 506-1 and 506-2 of the semiconductor structure 300 shown in FIGS. 8A and 8F have an elongated shape without any jog portions. More specifically, the metal conductors 506-1 and 506-2 shown in FIGS. 8A and 8F have a rectangle shape in entirety without the jog portions 506j discussed above. In some embodiments, the metal conductors 506-1 is fully separated from the 504-4 and the active area 302-1 in the Y-direction, and the metal conductors 506-2 is fully separated from the source/drain contact 504-4 and the active area 302-2 in the Y-direction, as shown in FIGS. 9A to 9F. Therefore, the metal conductors 506-1 and 506-2 are electrically isolated from the source/drain contact 504-4.

FIGS. 9A and 9B are top views (or layouts) of the semiconductor structure in the logic region of the IC chip, in accordance with some alternative embodiments of the present disclosure, in which FIG. 9A illustrates the features in the device region and the front-side interconnection structure, and FIG. 9B illustrates the features in the device region and the back-side interconnection structure.

FIG. 9C is an X-Z cross-sectional view of the semiconductor structure along the line A-A′ in FIGS. 9A and 9B, in accordance with some alternative embodiments of the present disclosure. FIG. 9D is an X-Z cross-sectional view of the semiconductor structure along the line B-B′ in FIGS. 9A and 9B, in accordance with some alternative embodiments of the present disclosure. FIG. 9E is a Y-Z cross-sectional view of the semiconductor structure along the line C-C′ in FIGS. 9A and 9B, in accordance with some alternative embodiments of the present disclosure. FIG. 9F is a Y-Z cross-sectional view of the semiconductor structure along the line D-D′ in FIGS. 9A and 9B, in accordance with some alternative embodiments of the present disclosure.

The semiconductor structure 300 shown in FIGS. 9A and 9F is similar to the semiconductor structure 300 shown in FIGS. 8A to 8F, except that the semiconductor structure 300 shown in FIGS. 9A and 9F further vias 902 (including vias 902-1, 902-2, 902-3, 902-4, 902-5, and 902-6), a CESL 904, and an IMD layer 906. The vias 902, the CESL 904, and the ILD layer 906 are disposed under (or at the back-side of) the transistors PT1 to PT4 and NT1 to NT4. The vias 902, the CESL 904, and the IMD layer 906 may also be referred to as back-side vias, back-side CESL, and back-side IMD layer, respectively. The materials of the vias 902, the CESL 904, and the IMD layer 906 are similar to the vias 406, the CESL 510, and the IMD layer 512.

As shown in FIGS. 9A to 9F, the vias 902 are in the CESL 904 and the IMD layer 906 and extend lengthwise in the Y-direction. Each of the vias 902 in the CESL 904 and the IMD layer 906 is vertically between and electrically connected to the respective source/drain contact 504 and the respective metal conductor 506, as shown in FIGS. 9A to 9F. In some embodiments, the vias 902 may have a rectangle shape in the top view, as shown in FIG. 9A. Furthermore, lengths of the vias 902 in the Y-direction are greater than lengths of the vias 406 in the Y-direction due to a wider space on the back-side of the semiconductor structure 300.

As shown in FIGS. 9A to 9F, the vias 902-1, 902-2, 902-3, 902-4, 902-5, and 902-6 are under and electrically connected to the source/drain contacts 504-1, 504-2, 504-3, 504-5, 504-6, and 504-7, respectively. The vias 902-1, 902-2, and 902-3 are over and electrically connected to the metal conductor 506-1, and the 902-4, 902-5, 902-6 are over and electrically connected to the metal conductor 506-2. In other words, the vias 902-1, 902-2, and 902-3 are respectively between and electrically connected to the source/drain contacts 504-1, 504-2, and 504-3 and the metal conductor 506-1, and the vias 902-4, 902-5, and 902-6 are respectively between and electrically connected to the source/drain contacts 504-5, 504-6, and 504-7 and the metal conductor 506-2, as shown in FIGS. 9A to 9F. Therefore, the vias 902 may further improve the isolation margin for the metal conductors 506-1 and 506-2 to the source/drain contact 504-4.

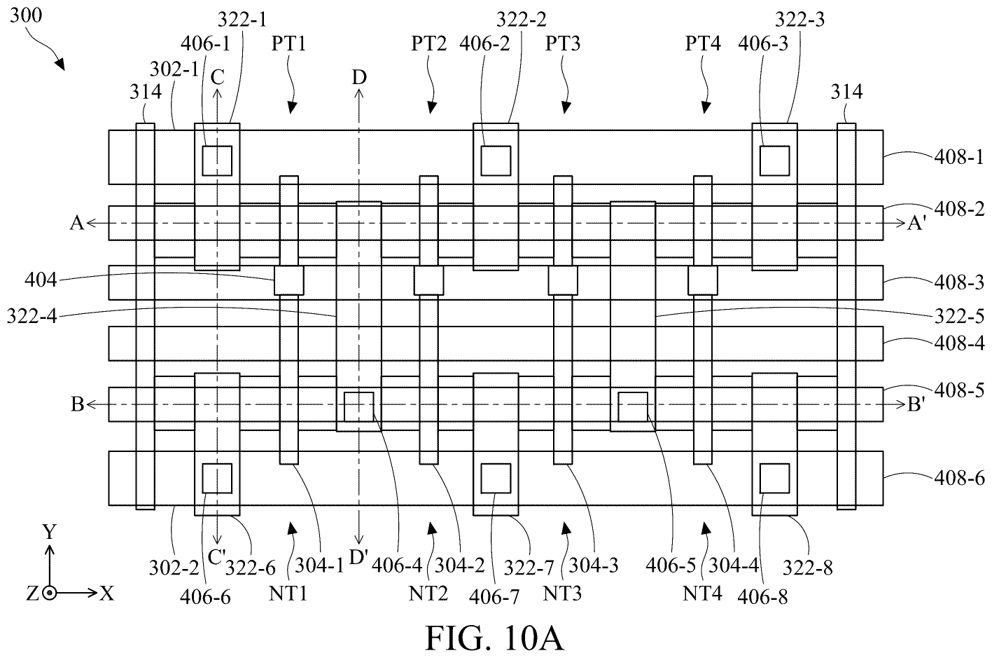

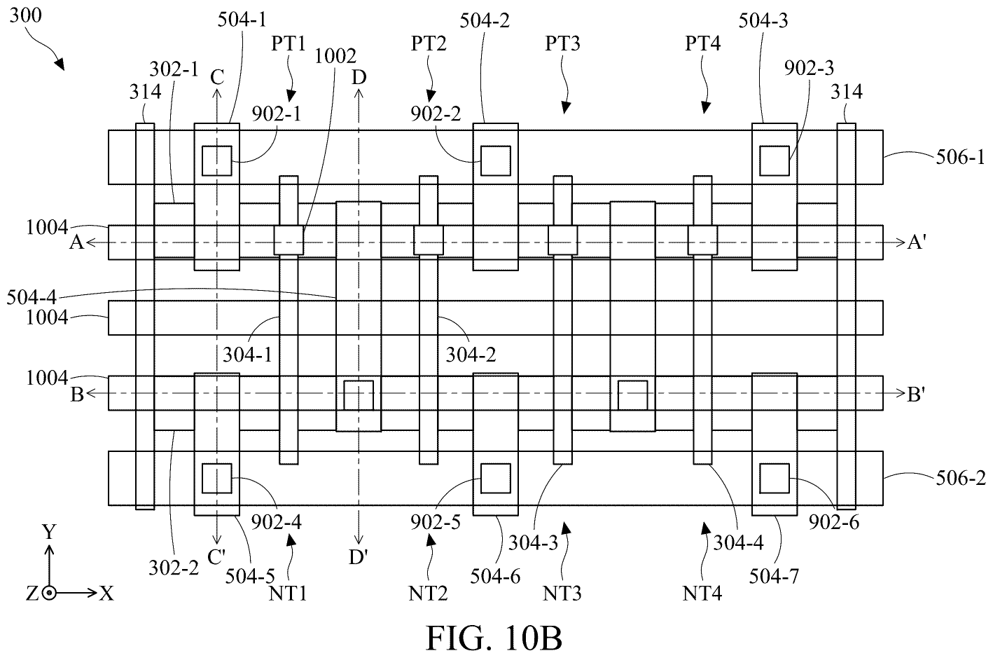

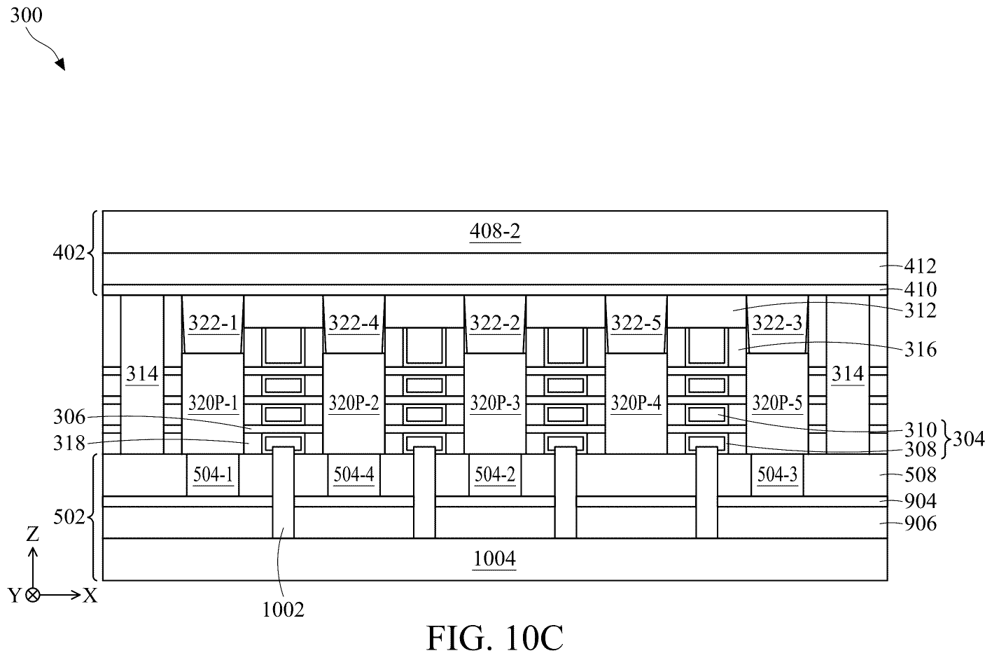

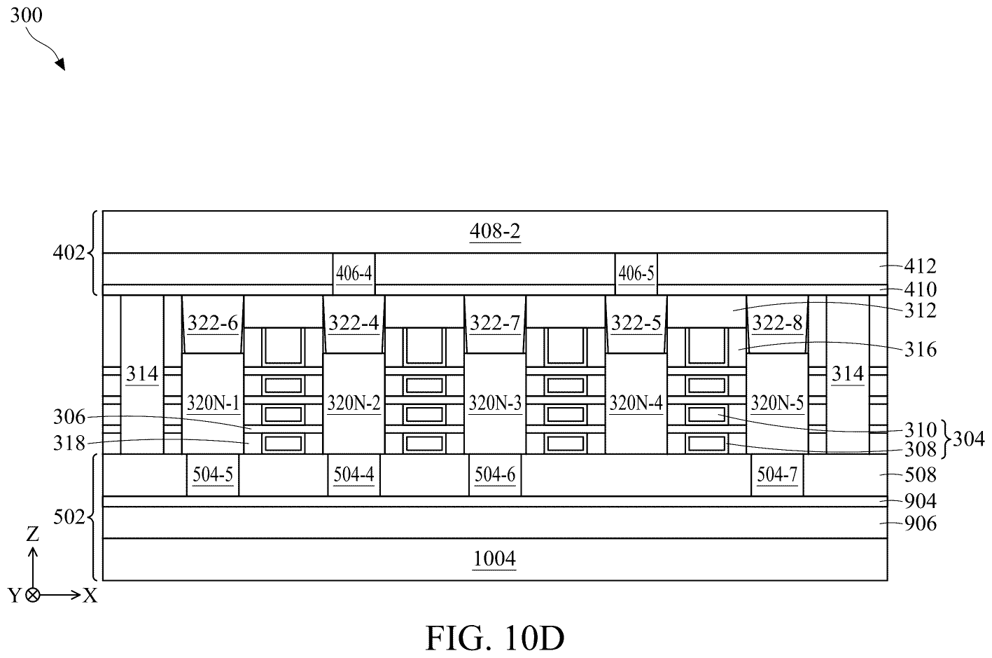

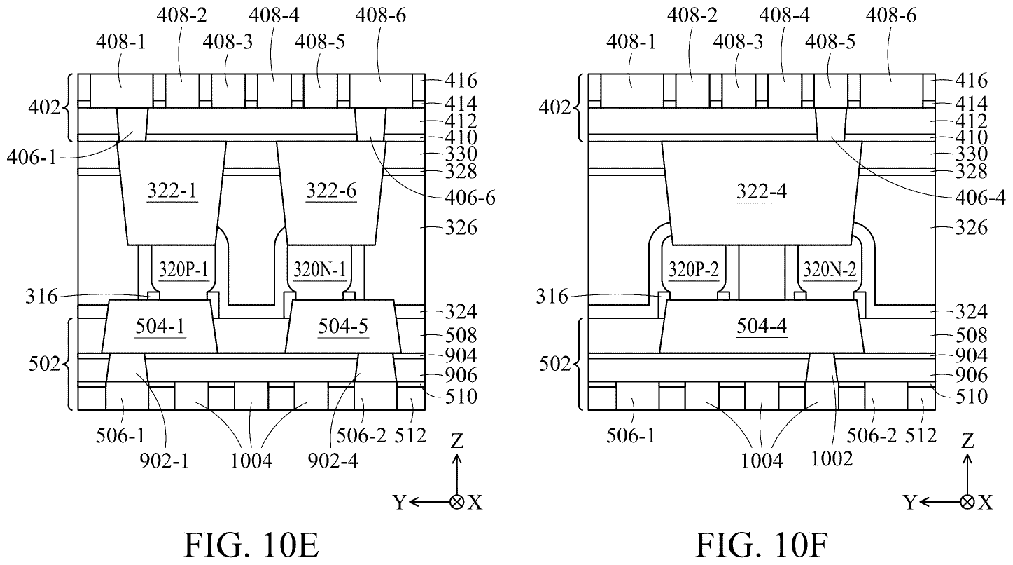

FIGS. 10A and 10B are top views (or layouts) of the semiconductor structure in the logic region of the IC chip, in accordance with some alternative embodiments of the present disclosure, in which FIG. 10A illustrates the features in the device region and the front-side interconnection structure, and FIG. 10B illustrates the features in the device region and the back-side interconnection structure.

FIG. 10C is an X-Z cross-sectional view of the semiconductor structure along the line A-A′ in FIGS. 10A and 10B, in accordance with some alternative embodiments of the present disclosure. FIG. 10D is an X-Z cross-sectional view of the semiconductor structure along the line B-B′ in FIGS. 10A and 10B, in accordance with some alternative embodiments of the present disclosure. FIG. 10E is a Y-Z cross-sectional view of the semiconductor structure along the line C-C′ in FIGS. 10A and 10B, in accordance with some alternative embodiments of the present disclosure. FIG. 10F is a Y-Z cross-sectional view of the semiconductor structure along the line D-D′ in FIGS. 10A and 10B, in accordance with some alternative embodiments of the present disclosure.

The semiconductor structure 300 shown in FIGS. 10A and 10F is similar to the semiconductor structure 300 shown in FIGS. 9A to 9F, except that the semiconductor structure 300 shown in FIGS. 10A and 10F further includes gate vias 1002 and metal conductors 1004. The gate vias 1002 and metal conductors 1004 are disposed under (or at the back-side of) the transistors PT1 to PT4 and NT1 to NT4. The gate vias 1002 and metal conductors 1004 may also be referred to as back-side gate vias and back-side metal conductors, respectively. The materials of the gate vias 1002 and metal conductors 1004 are similar to the gate vias 404 and the metal conductors 506.

As shown in FIGS. 10A to 10F, the metal conductors 1004 are in the CESL 510 and the IMD layer 512 and extend lengthwise in the X-direction. Each of the gate vias 1002 in the CESL 904 and the IMD layer 906 is vertically between and electrically connected to the respective gate structure 304 and the respective metal conductor 1004, as shown in FIGS. 10A to 10F.

As shown in FIGS. 10A to 10F, the gate vias 1002 are under and electrically connected to the gate structures 304-1, 304-2, 304-3, and 304-4, respectively. The gate vias 1002 are over and electrically connected to one of the metal conductors 1004. In other words, the gate vias 1002 are respectively between and electrically connected to the gate structures 304-1, 304-2, 304-3, and 304-4 and one of the metal conductors 1004, as shown in FIGS. 10A to 10F. Therefore, the one of the metal conductors 1004 is electrically connected to the gate structures 304-1, 304-2, 304-3, and 304-4. Furthermore, the metal conductors 1004 are disposed in the same level as the metal conductors 506. More specifically, the metal conductors 1004 are disposed in the CESL 510 and the ILD layer 512. In some embodiments, the metal conductors 1004 are also disposed between the metal conductors 506-1 and 506-2 in the Y-direction.

The embodiments disclosed herein relate to semiconductor structures, and more particularly to semiconductor structures including a back-side source/drain contact under and electrically connected to source/drain features of two adjacent transistors sharing the same gate structure. Furthermore, the present embodiments provide one or more of the following advantages. The source/drain features of two adjacent transistors sharing the same gate structure are connected with each other by not only a front-side source/drain contact but also the back-side source/drain contact, such that the resistance can be reduced. Furthermore, the metal conductors serving as the VDD line and the VSS line disposed on the back-side of the semiconductor structures can also reduce the resistance. The metal conductors serving as the VDD line and the VSS line have special configuration to be electrically isolated from the back-side source/drain contact.

Thus, one of the embodiments of the present disclosure describes a semiconductor structure that includes first transistor, a second transistor, a gate structure, and a first source/drain contact. The first transistor includes first nanostructures stacked from each other in a Z-direction, and a first source/drain feature and a second source/drain feature on opposite sides of the first nanostructures in an X-direction. The second transistor is arranged with the first transistor in a Y-direction. The second transistor includes second nanostructures stacked from each other in the Z-direction, and a third source/drain feature and a fourth source/drain feature on opposite sides of the second nanostructures in the X-direction. The gate structure extends in the Y-direction and wraps around the first nanostructures and the second nanostructures. The first source/drain contact extends in the Y-direction and is under and electrically connected to the second source/drain feature and the fourth source/drain feature.

In some embodiments, the semiconductor structure further includes a second source/drain contact extending in the Y-direction and over and electrically connected to the second source/drain feature and the fourth source/drain feature.

In some embodiments, the semiconductor structure further includes a second source/drain contact extending in the Y-direction and under and electrically connected to the first source/drain feature, a third source/drain contact extending in the Y-direction and under and electrically connected to the third source/drain feature, a VDD conductor extending in the X-direction and under and electrically connected to the second source/drain contact, and a VSS conductor extending in the X-direction and under and electrically connected to the third source/drain contact. The VDD conductor and the VSS conductor are electrically isolated from the first source/drain contact.

In some embodiments, the semiconductor structure further includes a first via between and electrically connected to the second source/drain contact and the VDD conductor, and a second via between and electrically connected to the third source/drain contact and the VSS conductor.

In some embodiments, each of the VDD conductor and the VSS conductor further includes two elongated portions separated from the first source/drain contact in the X-direction in a top view, and a jog portion between the two elongated portions. The jog portion is separated from the first source/drain contact in the Y-direction in the top view.

In some embodiments, the jog portion is separated from the first source/drain contact in the Y-direction by a first distance, wherein the first distance is greater than about 4 nm.

In some embodiments, an edge of the jog portion extending in the X-direction is offset from an edge of the elongated portions extending in the X-direction by a second distance in the Y-direction.

In some embodiments, an edge of the jog portion extending in the X-direction is aligned with an edge of the elongated portions extending in the X-direction.

In some embodiments, the VDD conductor and the VSS conductor partially overlap the first source/drain contact in a top view.

In some embodiments, the first source/drain contact is in contact with sidewalls of the second source/drain feature and the fourth source/drain feature.

In another of the embodiments, discussed is a semiconductor structure including first nanostructures, second nanostructures, a gate structure, a first source/drain feature and a second source/drain feature, a third source/drain feature and a fourth source/drain feature, a first source/drain contact, and a second source/drain contact. The first nanostructures are vertically stacked from each other. The second nanostructures are vertically stacked from each other. The gate structure extends in a Y-direction and wraps around the first nanostructures and the second nanostructures. The first source/drain feature and the second source/drain feature are electrically connected to the first nanostructures in an X-direction. The third source/drain feature and the fourth source/drain feature are electrically connected to the second nanostructures in the X-direction. The first source/drain contact is under and electrically connected to the second source/drain feature and the fourth source/drain feature. The second source/drain contact is over and electrically connected to the second source/drain feature and the fourth source/drain feature.

In some embodiments, the semiconductor structure further includes a third source/drain contact, a fourth source/drain contact, a first front-side via, a second front-side via, a front-side VDD conductor, and a front-side VSS conductor. The third source/drain contact is over and electrically connected to the first source/drain feature. The fourth source/drain contact is over and electrically connected to the third source/drain feature. The first front-side via is over and electrically connected to the third source/drain contact. The second front-side via is over and electrically connected to the fourth source/drain contact. The front-side VDD conductor extends in the X-direction and is over and electrically connected to the first front-side via. The front-side VSS conductor extends in the X-direction and is over and electrically connected to the second front-side via.

In some embodiments, the semiconductor structure further includes a fifth source/drain contact, a sixth source/drain contact, a back-side VDD conductor, and a back-side VSS conductor. The fifth source/drain contact is under and electrically connected to the first source/drain feature. The sixth source/drain contact is under and electrically connected to the third source/drain feature. The back-side VDD conductor extends in the X-direction and is under and electrically connected to the fifth source/drain contact. The back-side VSS conductor extends in the X-direction and is under and electrically connected to the sixth source/drain contact. The back-side VDD conductor and the back-side VSS conductor are electrically isolated from the first source/drain contact.

In some embodiments, the semiconductor structure further includes a first back-side via and a second back-side via. The first back-side via is between and electrically connected to the fifth source/drain contact and the back-side VDD conductor. The second back-side via is between and electrically connected to the sixth source/drain contact and the back-side VSS conductor. Lengths of the first back-side via and the second back-side via in the Y-direction are greater than lengths of the first front-side via and the second front-side via in the Y-direction.

In some embodiments, the back-side VDD conductor and the back-side VSS conductor are directly under the first source/drain contact.

In some embodiments, a distance between a bottom surface of the second source/drain feature and a bottom surface of the first source/drain contact is greater than a distance between a bottom surface of the fourth source/drain feature and the bottom surface of the first source/drain contact.

In yet another of the embodiments, discussed is a semiconductor structure including a first transistor, a second transistor, a gate structure, a back-side source/drain contact, a back-side VDD conductor, and a back-side VSS conductor. The first transistor includes first nanostructures stacked from each other in a Z-direction, and a first source/drain feature and a second source/drain feature attached to the first nanostructures in an X-direction. The second transistor is arranged with the first transistor in a Y-direction. The second transistor includes second nanostructures stacked from each other in the Z-direction, and a third source/drain feature and a fourth source/drain feature attached to the second nanostructures in the X-direction. The gate structure extends in the Y-direction and wraps around the first nanostructures and the second nanostructures. The back-side source/drain contact is under and in contact with the second source/drain feature and the fourth source/drain feature. The back-side VDD conductor extends in the X-direction and is under and electrically connected to the first source/drain feature. The back-side VSS conductor extends in the X-direction and is under and electrically connected to the third source/drain feature. The VDD conductor and the VSS conductor are electrically isolated from the first source/drain contact.

In some embodiments, the semiconductor structure further includes dielectric layers on sidewalls of the back-side source/drain contact.

In some embodiments, the back-side source/drain contact has an asymmetric shape in a Y-Z cross-sectional view.

In some embodiments, the semiconductor structure further includes back-side conductors extending in the X-direction and between the back-side VDD conductor and the back-side VSS conductor in the Y-direction. One of the back-side conductors is electrically connected to the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor, comprising:
first nanostructures stacked from each other in a Z-direction; and
a first source/drain feature and a second source/drain feature on opposite sides of the first nanostructures in an X-direction;
a second transistor arranged with the first transistor in a Y-direction, comprising:
second nanostructures stacked from each other in the Z-direction; and
a third source/drain feature and a fourth source/drain feature on opposite sides of the second nanostructures in the X-direction;
a gate structure extending in the Y-direction and wrapping around the first nanostructures and the second nanostructures; and
a first source/drain contact extending in the Y-direction and under and electrically connected to the second source/drain feature and the fourth source/drain feature.

2. The semiconductor structure of claim 1, further comprising:
a second source/drain contact extending in the Y-direction and over and electrically connected to the second source/drain feature and the fourth source/drain feature.

3. The semiconductor structure of claim 1, further comprising:
a second source/drain contact extending in the Y-direction and under and electrically connected to the first source/drain feature;
a third source/drain contact extending in the Y-direction and under and electrically connected to the third source/drain feature;
a VDD conductor extending in the X-direction and under and electrically connected to the second source/drain contact; and
a VSS conductor extending in the X-direction and under and electrically connected to the third source/drain contact, wherein the VDD conductor and the VSS conductor are electrically isolated from the first source/drain contact.

4. The semiconductor structure of claim 3, further comprising:
a first via between and electrically connected to the second source/drain contact and the VDD conductor; and
a second via between and electrically connected to the third source/drain contact and the VSS conductor.

5. The semiconductor structure of claim 3, wherein each of the VDD conductor and the VSS conductor further comprises:
two elongated portions separated from the first source/drain contact in the X-direction in a top view; and
a jog portion between the two elongated portions, wherein the jog portion is separated from the first source/drain contact in the Y-direction in the top view.

6. The semiconductor structure of claim 5, wherein the jog portion is separated from the first source/drain contact in the Y-direction by a first distance, wherein the first distance is greater than about 4 nm.

7. The semiconductor structure of claim 6, wherein an edge of the jog portion extending in the X-direction is offset from an edge of the elongated portions extending in the X-direction by a second distance in the Y-direction.

8. The semiconductor structure of claim 6, wherein an edge of the jog portion extending in the X-direction is aligned with an edge of the elongated portions extending in the X-direction.

9. The semiconductor structure of claim 3, wherein the VDD conductor and the VSS conductor partially overlap the first source/drain contact in a top view.

10. The semiconductor structure of claim 1, wherein the first source/drain contact is in contact with sidewalls of the second source/drain feature and the fourth source/drain feature.

11. A semiconductor structure, comprising:
first nanostructures vertically stacked from each other;
second nanostructures vertically stacked from each other;
a gate structure extending in a Y-direction and wrapping around the first nanostructures and the second nanostructures;
a first source/drain feature and a second source/drain feature electrically connected to the first nanostructures in an X-direction;
a third source/drain feature and a fourth source/drain feature electrically connected to the second nanostructures in the X-direction;
a first source/drain contact under and electrically connected to the second source/drain feature and the fourth source/drain feature; and
a second source/drain contact over and electrically connected to the second source/drain feature and the fourth source/drain feature.

12. The semiconductor structure of claim 11, further comprising:
a third source/drain contact over and electrically connected to the first source/drain feature;
a fourth source/drain contact over and electrically connected to the third source/drain feature;
a first front-side via over and electrically connected to the third source/drain contact;
a second front-side via over and electrically connected to the fourth source/drain contact;
a front-side VDD conductor extending in the X-direction and over and electrically connected to the first front-side via; and
a front-side VSS conductor extending in the X-direction and over and electrically connected to the second front-side via.

13. The semiconductor structure of claim 12, further comprising:
a fifth source/drain contact under and electrically connected to the first source/drain feature;
a sixth source/drain contact under and electrically connected to the third source/drain feature;
a back-side VDD conductor extending in the X-direction and under and electrically connected to the fifth source/drain contact; and
a back-side VSS conductor extending in the X-direction and under and electrically connected to the sixth source/drain contact, wherein the back-side VDD conductor and the back-side VSS conductor are electrically isolated from the first source/drain contact.

14. The semiconductor structure of claim 13, further comprising:
a first back-side via between and electrically connected to the fifth source/drain contact and the back-side VDD conductor; and
a second back-side via between and electrically connected to the sixth source/drain contact and the back-side VSS conductor,
wherein lengths of the first back-side via and the second back-side via in the Y-direction are greater than lengths of the first front-side via and the second front-side via in the Y-direction.

15. The semiconductor structure of claim 13, wherein the back-side VDD conductor and the back-side VSS conductor are directly under the first source/drain contact.

16. The semiconductor structure of claim 11, wherein a distance between a bottom surface of the second source/drain feature and a bottom surface of the first source/drain contact is greater than a distance between a bottom surface of the fourth source/drain feature and the bottom surface of the first source/drain contact.

17. A semiconductor structure, comprising:
a first transistor, comprising:
first nanostructures stacked from each other in a Z-direction; and
a first source/drain feature and a second source/drain feature attached to the first nanostructures in an X-direction;
a second transistor arranged with the first transistor in a Y-direction, comprising:
second nanostructures stacked from each other in the Z-direction; and
a third source/drain feature and a fourth source/drain feature attached to the second nanostructures in the X-direction;
a gate structure extending in the Y-direction and wrapping around the first nanostructures and the second nanostructures;
a back-side source/drain contact under and in contact with the second source/drain feature and the fourth source/drain feature;
a back-side VDD conductor extending in the X-direction and under and electrically connected to the first source/drain feature; and
a back-side VSS conductor extending in the X-direction and under and electrically connected to the third source/drain feature, wherein the VDD conductor and the VSS conductor are electrically isolated from the first source/drain contact.

18. The semiconductor structure of claim 17, further comprising:
dielectric layers on sidewalls of the back-side source/drain contact.

19. The semiconductor structure of claim 17, wherein the back-side source/drain contact has an asymmetric shape in a Y-Z cross-sectional view.

20. The semiconductor structure of claim 17, further comprising:
back-side conductors extending in the X-direction and between the back-side VDD conductor and the back-side VSS conductor in the Y-direction, wherein one of the back-side conductors is electrically connected to the gate structure.
